(19) United States
(12) Patent Application Publication
(10) Pub. No.: US 2025/0034319 A1
(43) Pub. Date: Jan. 30, 2025

(54) EPOXY RESIN COMPOSITION, CURED PRODUCT, ENCAPSULANT AND ADHESIVE

(71) Applicant: ASAHI KASEI KABUSHIKI KAISHA, Tokyo (JP)

(72) Inventors: Ryosuke OKAMOTO, Tokyo (JP); Naoya KAMIMURA, Tokyo (JP); Kenzo ONIZUKA, Tokyo (JP)

(73) Assignee: ASAHI KASEI KABUSHIKI KAISHA, Tokyo (JP)

(21) Appl. No.: 18/713,564

(22) PCT Filed: Dec. 26, 2022
(86) PCT No.: PCT/JP2022/047933

§ 371 Date: May 24, 2024

(30) Foreign Application Priority Data
Dec. 28, 2021 (JP) 2021-213746

(51) Int. Cl. C08G 59/40; C08K 3/013; C08K 5/00; C09J 163/00; H01L 23/29

(52) U.S. Cl. CPC C08G 59/4035; C08K 3/013; C08K 5/005; C09J 163/00; H01L 23/295; C08G 2170/00

(57) ABSTRACT

Provided is an epoxy resin composition containing (A) epoxy resin, and (B) a heteroatom-containing curing agent, wherein molecular weight α of the heteroatom-containing curing agent (B) is 200≤α≤1200, and ratio α/β of the molecular weight α to number β of heteroatoms in a structure of the heteroatom-containing curing agent (B) is 30≤α/β≤95.

### TECHNICAL FIELD

The present invention relates to an epoxy resin composition, a cured product, an encapsulant and an adhesive.

### BACKGROUND ART

Epoxy resin has been used in a wide range of applications such as coating materials, electric or electronic insulating materials, and adhesives because its cured product has excellent performance in terms of mechanical characteristics, electric characteristics, thermal characteristics, chemical resistance, adhesion, and the like.

Patent Document 1 given below discloses a resin for use in semiconductor packages. Current epoxy resin compositions generally used are so-called two-component epoxy resin compositions in which epoxy resin and a curing agent are mixed when used.

The two-component epoxy resin compositions are capable of being cured at room temperature, whereas storage or handling is complicated because the epoxy resin and the curing agent need to be separately stored and used after being weighed and mixed, if necessary. In addition, these components cannot be mixed in advance in large amounts due to a limited available time, leading to problems, i.e., an increased frequency of blending and inevitable reduction in efficiency.

Some one-component epoxy resin compositions have been proposed so far for the purpose of solving the problems of such two-component epoxy resin compositions. Examples thereof include epoxy resin compositions containing a latent curing agent blended with epoxy resin. Patent Document 2 discloses an epoxy resin composition using liquid aromatic amines.

There are requirements including downsizing, high functionality, lightening, high functionality, and multifunctionality for current electronic devices. For example, semiconductor chip packaging techniques are also required to attain further miniaturization, downsizing, and high densification brought about by finer pitches of electrode pads and pad pitches. Furthermore, there are underfills as adhesives that are used in the space between chips and substrates to protect bump connections and chip circuit surfaces. Such underfills are required to penetrate narrower gaps and exhibit favorable adhesion, in association with finer pitches.

### CITATION LIST

### Patent Document

Patent Document 1: Japanese Patent No. 6282515
Patent Document 2: Japanese Patent Laid-Open No. 2019-172738

### SUMMARY OF INVENTION

### Technical Problem

As mentioned above, latent curing agents that constitute one-component epoxy resin compositions are required to achieve both favorable curability and storage stability after being mixed with epoxy resin, and further required to have favorable penetration and adhesion into narrow gap sites of electronic members or between dense fibers such as carbon fibers or glass fibers.

Patent Document 1 discloses a resin composition using an aromatic amine compound as a curing agent. However, a problem thereof is that the curing agent used is solid and finds the difficulty in penetrating narrow gaps.

Patent Document 2 discloses an epoxy resin composition using a liquid aromatic amine compound as a curing agent. However, a problem thereof is that storage or handleability is complicated because an additive needs to be added for improving the storage stability and adhesion of the curing agent.

Accordingly, in light of the circumstances mentioned above, an object of the present invention is to provide an epoxy resin composition having favorable adhesion, a cured product of the epoxy resin composition, an encapsulant, and an adhesive.

### Solution to Problem

The present inventors have conducted diligent studies to attain the object mentioned above, and consequently completed the present invention by finding that the object mentioned above can be solved by an epoxy resin composition containing a specific curing agent, wherein the molecular weight of the curing agent and the number of heteroatoms in its structure fall within specific ranges.

Specifically, the present invention is as follows.

[1] An epoxy resin composition containing
(A) epoxy resin, and
(B) a heteroatom-containing curing agent, wherein
molecular weight α of the heteroatom-containing curing agent (B) is 200≤α≤1200, and
ratio α/β of the molecular weight α to number β of heteroatoms in a structure of the heteroatom-containing curing agent (B) is 30≤α/β≤95.

[2] The epoxy resin composition according to [1], wherein the heteroatom-containing curing agent (B) contains an aminimide compound represented by the following formula (1), (2) or (3):

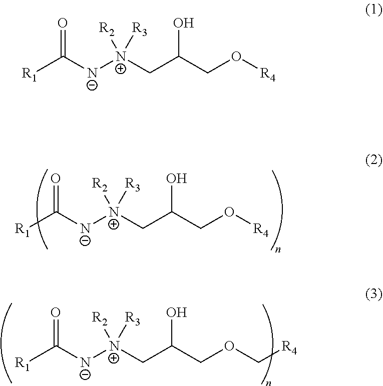

wherein each R₁ independently represents a hydrogen atom, or a monovalent or n-valent organic group having 1 to 15 carbon atoms and optionally having a hydroxy group, a carbonyl group, an ester bond, or an ether bond; R₂ and R₃ each independently represent an unsubstituted or substituted alkyl group having 1 to 12 carbon atoms, aryl group, aralkyl group, or heterocyclic ring having 7 or less carbon atoms in which R₂ and R₃ are linked to each other; each R₄ independently represents a hydrogen atom, or a monovalent or n-valent organic group having 1 to 30 carbon atoms and optionally containing an oxygen atom; and n represents an integer of 1 to 3.

[3] The epoxy resin composition according to [2], wherein the n in the formula (2) or (3) is 2 or 3.

[4] The epoxy resin composition according to any one of [1] to [3], further containing (C) an inorganic filler.

[5] The epoxy resin composition according to [4], wherein a content of the inorganic filler (C) is more than 5% by mass and 98% by mass or less based on the whole epoxy resin composition.

[6] The epoxy resin composition according to any one of [1] to [5], further containing (D) a stabilizer.

[7] The epoxy resin composition according to [6], wherein the stabilizer (D) contains a compound represented by the following formula (A) or (B):

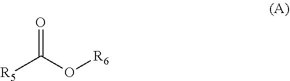

wherein R₅ and R₆ each independently represent a hydrogen atom, or a monovalent or n-valent organic group having 1 to 15 carbon atoms and optionally having a hydroxy group, a carbonyl group, an ester bond, or an ether bond; and n represents an integer of 2 to 3,

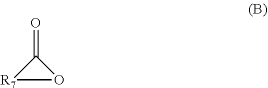

wherein R₇ represents a monovalent or n-valent organic group having 1 to 15 carbon atoms and optionally having a hydroxy group, a carbonyl group, an ester bond, or an ether bond; and n represents an integer of 2 to 3.

[8] The epoxy resin composition according to [6] or [7], wherein a content of the stabilizer (D) is 1 part by mass or more and 30 parts by mass or less based on 100 parts by mass of the epoxy resin (A).

[9] A cured product of an epoxy resin composition according to any one of [1] to [8].

[10] An encapsulant containing a cured product according to [9].

[11] The encapsulant according to [10], wherein the encapsulant is an encapsulant for a semiconductor.

[12] An adhesive containing an epoxy resin composition according to any one of [1] to [8].

### Advantageous Effects of Invention

The present invention can provide an epoxy resin composition having favorable adhesion, a cured product of the epoxy resin composition, an encapsulant, and an adhesive.

### DESCRIPTION OF EMBODIMENTS

Hereinafter, the mode for carrying out the present invention (hereinafter, referred to as the “present embodiment”) will be described in detail. The present embodiment is given for illustrating the present invention and does not intend to limit the present invention to the contents described below. The present invention can be carried out by appropriately making changes or modifications without departing from the spirit of the present invention.

### [Epoxy Resin Composition]

The epoxy resin composition of the present embodiment contains (A) epoxy resin, and (B) a heteroatom-containing curing agent (hereinafter, also referred to as a curing agent (B)), wherein molecular weight α of the heteroatom-containing curing agent (B) (hereinafter, also simply referred to as “molecular weight α”) is 200≤α≤1200, and ratio α/β of the molecular weight α to number β of heteroatoms in a structure of the heteroatom-containing curing agent (B) (hereinafter, also simply referred to as “number β of heteroatoms”) is 30≤α/β≤95.

The epoxy resin composition of the present embodiment configured as mentioned above is excellent in adhesion. This is presumably because of the following factors, though the factors are not limited thereto.

Specifically, when the molecular weight α of the heteroatom-containing curing agent (B) is 200 or larger, a cross-link length is increased during curing to produce a strong structure. This can suppress the cohesive failure of a cured product, presumably improving adhesion. On the other hand, when the molecular weight α of the heteroatom-containing curing agent (B) is 1200 or smaller, the curing agent (B) is excellent in dispersibility and thus sufficiently disperses the epoxy resin (A) and can exert sufficient curability. As a result, sufficient adhesive strength is presumably obtained.

When the value of the ratio α/β of the molecular weight α to number β of heteroatoms in a structure of the curing agent (B) is 95 or less, the number of polar functional groups in the heteroatom-containing curing agent (B) is increased. The resulting epoxy resin composition of the present embodiment presumably adheres strongly to an adherend through an intermolecular bond. On the other hand, when the ratio α/β of the molecular weight α to number β of heteroatoms in a structure of the heteroatom-containing curing agent (B) is 30 or more, the epoxy resin composition can be sufficiently cured owing to high compatibility between the curing agent (B) and the epoxy resin (A). As a result, sufficient adhesive strength can presumably be obtained.

In the epoxy resin composition of the present embodiment, the lower limit value of the molecular weight α of the heteroatom-containing curing agent (B) is 200 or larger, preferably 220 or larger, more preferably 250 or larger. The upper limit value of the molecular weight α of the heteroatom-containing curing agent (B) is 1200 or smaller, preferably 1100 or smaller, more preferably 1000 or smaller, further preferably 900.

The molecular weight α of the heteroatom-containing curing agent (B) can be measured with a mass spectrometer (ESI-MS).

In the epoxy resin composition of the present embodiment, the lower limit value of the ratio α/β of the molecular weight α to number β of heteroatoms in a structure of the heteroatom-containing curing agent (B) is 30 or more, preferably 35 or more, more preferably 40 or more. The upper limit value of the ratio α/β is 95 or less, preferably 90 or less, more preferably 80 or less.

The number β of heteroatoms in the structure of the heteroatom-containing curing agent (B) can be measured with a mass spectrometer (ESI-MS).

The number β of heteroatoms in the structure of the heteroatom-containing curing agent (B) is not particularly limited and is preferably 5 or more and 25 or less, more preferably 5 or more and 20 or less, further preferably 5 or more and 15 or less, from the viewpoint of compatibility with the epoxy resin (A).

The molecular weight α and the value of the ratio α/β can be controlled within the numeric ranges described above by converting a molecular structure through chemical reaction in the step of preparing the heteroatom-containing curing agent (B).

### (Epoxy Resin (A))

The epoxy resin composition of the present embodiment contains epoxy resin (A).

Examples of the epoxy resin (A) include, but are not limited to: difunctional epoxy resins such as bisphenol A-type epoxy resin, bisphenol F-type epoxy resin, bisphenol AD-type epoxy resin, bisphenol M-type epoxy resin, bisphenol P-type epoxy resin, tetrabromobisphenol A-type epoxy resin, biphenyl-type epoxy resin, tetramethylbiphenyl-type epoxy resin, tetrabromobiphenyl-type epoxy resin, diphenyl ether-type epoxy resin, benzophenone-type epoxy resin, phenyl benzoate-type epoxy resin, diphenyl sulfide-type epoxy resin, diphenyl sulfoxide-type epoxy resin, diphenyl sulfone-type epoxy resin, diphenyl disulfide-type epoxy resin, naphthalene-type epoxy resin, anthracene-type epoxy resin, hydroquinone-type epoxy resin, methylhydroquinone-type epoxy resin, dibutylhydroquinone-type epoxy resin, resorcinol-type epoxy resin, methylresorcinol-type epoxy resin, catechol-type epoxy resin, N,N-diglycidyl aniline-type epoxy resin, ethylene oxide-added bisphenol A-type epoxy resin, propylene oxide-added bisphenol A-type epoxy resin, ethylene oxide-added bisphenol F-type epoxy resin, and propylene oxide-added bisphenol F-type epoxy resin; trifunctional epoxy resins such as trisphenol-type epoxy resin, N,N-diglycidyl aminobenzene-type epoxy resin, o-(N,N-diglycidyl amino) toluene-type epoxy resin, triazine-type epoxy resin, ethylene oxide-added trisphenol-type epoxy resin, and propylene oxide-added trisphenol-type epoxy resin; tetrafunctional epoxy resins such as tetraglycidyl diaminodiphenylmethane-type epoxy resin and diaminobenzene-type epoxy resin; polyfunctional epoxy resins such as phenol novolac-type epoxy resin, cresol novolac-type epoxy resin, triphenylmethane-type epoxy resin, tetraphenylethane-type epoxy resin, dicyclopentadiene-type epoxy resin, naphthol aralkyl-type epoxy resin, and brominated phenol novolac-type epoxy resin; and alicyclic epoxy resins.

These epoxy resins may each be used singly or may be used in combination of two or more thereof.

Epoxy resin obtained by modifying any of these resins with isocyanate or the like can also be used in combination therewith.

Although the epoxy resin mentioned above is not particularly limited, for example, bisphenol F-type epoxy resin alone, bisphenol F-type epoxy resin and bisphenol A-type epoxy resin in combination, or bisphenol F-type epoxy resin and naphthalene-type epoxy resin in combination can be suitably used.

In the epoxy resin composition of the present embodiment, the content of the epoxy resin (A) is not particularly limited and is preferably 60% by mass or more and 95% by mass or less, more preferably 65% by mass or more and 90% by mass or less, further preferably 70% by mass or more and 85% by mass or less, based on the liquid component of the epoxy resin composition.

When the content of the epoxy resin (A) falls within the range mentioned above, high adhesion tends to be obtained.

### (Heteroatom-Containing Curing Agent (B))

The epoxy resin composition of the present embodiment contains a heteroatom-containing curing agent (B).

The heteroatom-containing curing agent (B) is a curing agent that satisfies the conditions of the molecular weight α and the ratio α/β mentioned above.

The heteroatom-containing curing agent (B) is not particularly limited as long as the curing agent has a heteroatom. The curing agent preferably has a heteroatom in the backbone. The curing agent having a heteroatom in the backbone is not particularly limited and is preferably a curing agent having a nitrogen atom and/or an oxygen atom in the backbone, more preferably a curing agent having a N—N bond in the backbone, from the viewpoint of functioning as a latent curing agent. The following aminimide compound can be suitably used as the heteroatom-containing curing agent (B) from the viewpoint of functioning as a latent curing agent.

The heteroatom-containing curing agent (B) preferably contains an aminimide compound represented by the following formula (1), (2) or (3) (hereinafter, also referred to as the “aminimide compound according to the present embodiment”) from the viewpoint that the epoxy resin composition of the present embodiment is excellent in penetration and has excellent curability and storage stability.

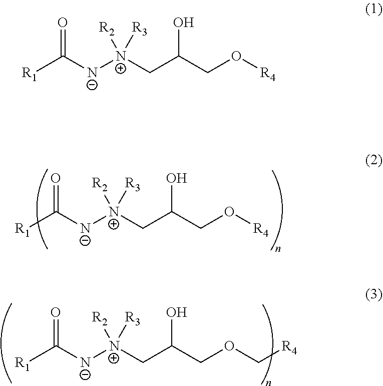

In the formulas (1) to (3), each R₁ independently represents a hydrogen atom, or a monovalent or n-valent organic group having 1 to 15 carbon atoms and optionally having a hydroxy group, a carbonyl group, an ester bond, or an ether bond; R₂ and R₃ each independently represent an unsubstituted or substituted alkyl group having 1 to 12 carbon atoms, aryl group, aralkyl group, or heterocyclic ring having 7 or less carbon atoms in which R₂ and R₃ are linked to each other; each R₄ independently represents a hydrogen atom, or a monovalent or n-valent organic group having 1 to 30 carbon atoms and optionally containing an oxygen atom; and n represents an integer of 1 to 3.

The aminimide compound according to the present embodiment is preferably a liquid compound at ordinary temperature. In the present embodiment, a viscosity at 25° C. can be used as an index that indicates being “liquid at ordinary temperature”. In addition, the viscosity at 25° C. of the aminimide compound according to the present embodiment is preferably 1300 Pa·s or less, more preferably 900 Pa·s or less, further preferably 800 Pa·s or less, still further preferably 700 Pa·s or less, from the viewpoint that solubility or dispersibility in the epoxy resin composition of the present embodiment and penetration into a base material or the like are more improved. The lower limit value of the viscosity at 25° C. is not particularly limited and is preferably 0.01 Pa·s or more. The viscosity of the aminimide compound according to the present embodiment can be controlled, for example, by adjusting the functional groups R₁ to R₄ in the formulas (1) to (3). The viscosity (Pa·s) at 25° C. of the aminimide compound according to the present embodiment can be measured, for example, by adding dropwise the aminimide compound (approximately 0.3 mL) to a measurement cup and performing measurement using a type E viscometer (“TVE-35H” manufactured by Toki Sangyo Co., Ltd.) 15 minutes after the sample temperature reaches 25° C.

In the formulas (2) and (3), n represents an integer of 1 to 3. n in the formulas (2) and (3) is preferably 2 or 3 from the viewpoint of the adhesion of the epoxy resin composition of the present embodiment.

In the formulas (1), (2) and (3), each R₁ independently represents a hydrogen atom, or a “monovalent or n-valent organic group having 1 to 15 carbon atoms and optionally having a hydroxy group, a carbonyl group, an ester bond or an ether bond”. Examples of such an organic group include, but are not particularly limited to, “hydrocarbon groups”, “groups in which a hydrogen atom bonded to a carbon atom in a hydrocarbon group is replaced with a hydroxy group or a carbonyl group”, and “groups in which one or some carbon atoms constituting a hydrocarbon group are replaced with an ester bond or an ether bond”.

Examples of the hydrocarbon group include: linear, branched, or cyclic alkyl groups such as a methyl group, an ethyl group, a propyl group, a butyl group, a pentyl group, a hexyl group, a heptyl group, an octyl group, and an ethylhexyl group; alkenyl groups such as a vinyl group, a propynyl group, a butynyl group, a pentynyl group, a hexynyl group, an octynyl group, a decynyl group, a dodecynyl group, a hexadecynyl group, and an octadecynyl group; aryl groups such as a phenyl group; and aralkyl groups composed of combinations of an alkyl group and a phenyl group, such as a methylphenyl group, an ethylphenyl group, and a propylphenyl group.

The organic group represented by R₁ in the formulas (1) to (3) may be unsubstituted or may have an additional substituent. Examples of the substituent include, but are not particularly limited to, a halogen atom, an alkoxy group, a carbonyl group, a cyano group, an azo group, an azi group, a thiol group, a sulfo group, a nitro group, a hydroxy group, an acyl group, and an aldehyde group.

The number of carbon atoms in the organic group represented by R₁ in the formulas (1) to (3) is 1 to 15, preferably 1 to 12, more preferably 1 to 7. When the number of carbon atoms in the organic group represented by R₁ falls within the range mentioned above, the curing performance of the aminimide compound represented by any of the formulas (1) to (3) tends to be more improved. When the number of carbon atoms in the organic group represented by R₁ falls within the range mentioned above, the ease of obtainment of a starting material for preparing the formulas (1) to (3) is more improved.

Among those mentioned above, the organic group represented by R₁ in the formula (1) or (3) is preferably a group represented by the formula (4) or (5) given below. By having the group represented by the following formula (4) or (5) as R₁ in the formulas (1) or (3), the curing performance of the aminimide compound tends to be more improved.

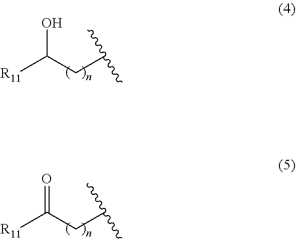

In the formulas (4) and (5), each R₁₁ independently represents an alkyl group having 1 to 5 carbon atoms, an alkoxy group having 1 to 5 carbon atoms, an aryl group, or an aralkyl group having 7 to 9 carbon atoms, and each n independently represents an integer of 0 to 6.

Among those mentioned above, a group of the formula (5) wherein n is 0 or 1 is preferred. The aminimide compound represented by the formula (1) or (3) thereby has a diketone structure in the R₁—C(═O)— structure. Such a diketone structure tends to more improve the curing performance of the aminimide compound.

The number of carbon atoms in R₁₁ and n in the formula (4) or (5) are adjusted such that the maximum value of the number of carbon atoms in the group represented by the formula (4) or (5) does not exceed 15. Examples of the alkyl group having 1 to 5 carbon atoms, the alkoxy group having 1 to 5 carbon atoms, the aryl group, or the aralkyl group having 7 to 9 carbon atoms in R₁₁ include the same as those listed in the organic group represented by R₁ mentioned above.

The organic group represented by R₁ in the formula (2) is preferably a group represented by the formula (6) or (7) given below. By having the group represented by the following formula (6) or (7) as R₁ in the formula (2), a liquid aminimide compound at ordinary temperature is easily obtained. Furthermore, the curing performance of the aminimide compound tends to be more improved.

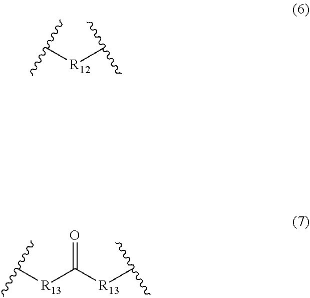

In the formulas (6) and (7), R₁₂ and R₁₃ each independently represent a single bond, an alkyl group having 1 to 5 carbon atoms, an aryl group, or an aralkyl group having 7 to 9 carbon atoms.

Among those mentioned above, R₁₃ in the formula (7) is preferably a single bond or a methyl group. The aminimide compound represented by the formula (2) thereby has a diketone structure in the R₁—C(═O)— structure. Such a diketone structure tends to more improve the curing performance of the aminimide compound. Examples of the alkyl group having 1 to 5 carbon atoms, the aryl group, or the aralkyl group having 7 to 9 carbon atoms in R₁₂ and R₁₃ include the same as those listed in the organic group represented by R₁ mentioned above.

In the formulas (1), (2) and (3), R₂ and R₃ each independently represent an unsubstituted or substituted alkyl group having 1 to 12 carbon atoms, aryl group, aralkyl group, or heterocyclic ring having 7 or less carbon atoms in which R₂ and R₃ are linked to each other.

Examples of the alkyl group having 1 to 12 carbon atoms represented by R₂ or R₃ include, but are not limited to: linear alkyl groups such as a methyl group, an ethyl group, a propyl group, a n-butyl group, a n-pentyl group, a n-hexyl group, a n-octyl group, a n-decyl group, and a n-dodecyl group; branched alkyl groups such as an isopropyl group, an isobutyl group, a t-butyl group, a neopentyl group, a 2-hexyl group, a 2-octyl group, a 2-decyl group, and a 2-dodecyl group; and cyclic alkyl groups such as a cyclopropyl group, a cyclobutyl group, a cyclopentyl group, a cyclohexyl group, a cyclooctyl group, a cyclodecyl group, and a cyclododecyl group.

The alkyl group mentioned above may be a combination of a linear alkyl group or a branched alkyl group and a cyclic alkyl group. The alkyl group mentioned above may further contain an unsaturated bonding group.

The number of carbon atoms in each alkyl group represented by R₂ or R₃ is independently 1 to 12, preferably 2 to 10, more preferably 5 to 10. The number of carbon atoms in the alkyl group represented by R₂ or R₃ is preferably 2 or more from the viewpoint of handleability. When the number of carbon atoms in the alkyl group represented by R₂ or R₃ is 5 or more, a liquid aminimide compound at ordinary temperature is easily obtained. Furthermore, the curing performance of the aminimide compound tends to be more improved.

Examples of the aryl group represented by R₂ or R₃ include, but are not limited to, a phenyl group and a naphthyl group.

Examples of the aralkyl group represented by R₂ or R₃ include, but are not limited to, a methylphenyl group, an ethylphenyl group, a methylnaphthyl group, and a dimethylnaphthyl group. Among them, at least one of R₂ and R₃ is preferably an aralkyl group, more preferably a methylphenyl group (benzyl group). The curing performance of the aminimide compound thereby tends to be more improved.

The number of carbon atoms in the aryl group or the aralkyl group represented by R₂ or R₃ is not particularly limited and is preferably 6 or more and 20 or less.

Examples of the substituent for the alkyl group, the aryl group, or the aralkyl group represented by R₂ or R₃ include, but are not limited to, a halogen atom, an alkoxy group, a carbonyl group, a cyano group, an azo group, an azi group, a thiol group, a sulfo group, a nitro group, a hydroxy group, an acyl group, and an aldehyde group.

R₂ and R₃ may be linked to each other to constitute a heterocyclic ring having 7 or less carbon atoms. Examples of such a heterocyclic ring include, but are not limited to, a heterocyclic ring formed by R₂₃ and N⁺ in the formula (1), (2) or (3) and represented by the formula (8) given below. R₂₃ represents a group in which R₂ and R₃ are linked to each other.

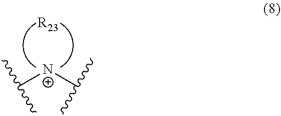

In the formula (8), R₂₃ represents a group that forms a heterocyclic structure together with N⁺.

Examples of the heterocyclic ring formed by R₂₃ and N⁺ include, but are not limited to: 4-membered rings such as an azetidine ring; 5-membered rings such as a pyrrolidine ring, a pyrrole ring, a morpholine ring, and a thiazine ring; 6-membered rings such as a piperidine ring; and 7-membered rings such as a hexamethyleneimine ring and an azepine ring.

Among them, the heterocyclic ring is preferably a pyrrole ring, a morpholine ring, a thiazine ring, a piperidine ring, a hexamethyleneimine ring, or an azepine ring, more preferably a 6-membered ring or a 7-membered ring. By having such a group, a liquid aminimide compound at ordinary temperature is easily obtained. Furthermore, the curing performance of the aminimide compound tends to be more improved.

Examples of the substituent in the heterocyclic ring having 7 or less carbon atoms constituted by linkage include, but are not limited to, an alkyl group, an aryl group, and the substituent mentioned above for R₂ and R₃. When the heterocyclic ring has an alkyl group as a substituent, examples thereof can include a methyl group bonded to the carbon atom adjacent to N⁺.

In the formulas (1), (2) and (3), each R₄ independently represents a hydrogen atom, or a “monovalent or n-valent organic group having 1 to 30 carbon atoms and optionally containing an oxygen atom”. Examples of such an organic group include, but are not limited to, “hydrocarbon groups”, “groups in which a hydrogen atom bonded to a carbon atom in a hydrocarbon group is replaced with a hydroxy group, a carbonyl group, or a group containing a silicon atom”, and “groups in which one or some carbon atoms constituting a hydrocarbon group are replaced with an ester bond, an ether bond, or a silicon atom”.

Examples of the hydrocarbon group represented by R₄ include, but are not limited to: linear, branched, or cyclic alkyl groups such as a methyl group, an ethyl group, a propyl group, a butyl group, a pentyl group, a hexyl group, a heptyl group, an octyl group, and an ethylhexyl group; alkenyl groups such as a vinyl group, a propynyl group, a butynyl group, a pentynyl group, a hexynyl group, an octynyl group, a decynyl group, a dodecynyl group, a hexadecynyl group, and an octadecynyl group; aryl groups such as a phenyl group; and aralkyl groups composed of combinations of an alkyl group and a phenyl group, such as a methylphenyl group, an ethylphenyl group, and a propylphenyl group.

Alternatively, the hydrocarbon group represented by R₄ contains a bisphenol skeleton such as a bisphenol A-type skeleton, a bisphenol AP-type skeleton, a bisphenol B-type skeleton, a bisphenol C-type skeleton, a bisphenol E-type skeleton, or a bisphenol F-type skeleton. Examples of the organic group containing the bisphenol skeleton include, but are not limited to, groups in which a polyoxyalkylene group is added to a hydroxy group of each bisphenol skeleton.

Among them, the organic group represented by R₄ in the formula (1) or (2) is preferably an alkyl group, an alkenyl group, or an aralkyl group, more preferably an alkyl group or an alkenyl group, further preferably a branched alkyl group or a branched alkenyl group. These preferred groups may have a substituent. By having such a group, the curing performance of the aminimide compound tends to be more improved. Moreover, the glass transition temperature (Tg) of a cured product obtained using the aminimide compound tends to be more improved.

The number of carbon atoms in the organic group represented by R₄ is 1 to 30, preferably 1 to 20, more preferably 1 to 15, further preferably 1 to 8. When the number of carbon atoms in the organic group represented by R₄ falls within the range mentioned above, the curing performance of the aminimide compound tends to be more improved. Moreover, Tg of a cured product obtained using the aminimide compound is more improved. When the number of carbon atoms in the organic group represented by R₄ falls within the range mentioned above, the ease of obtainment of a starting material for preparing the aminimide compound is more improved.

Among those mentioned above, R₄ in the formula (1) or (2) is preferably a linear or branched alkyl group having 3 to 12 carbon atoms, or a linear or branched alkenyl group having 3 to 6 carbon atoms. By having such a group, the curing performance of the aminimide compound tends to be more improved.

R₄ in the formula (3) is preferably a group represented by the formula (9) or (10) given below. By having the group represented by the following formula (9) or (10) as R₄ in the formula (3), the curing performance of the aminimide compound tends to be more improved.

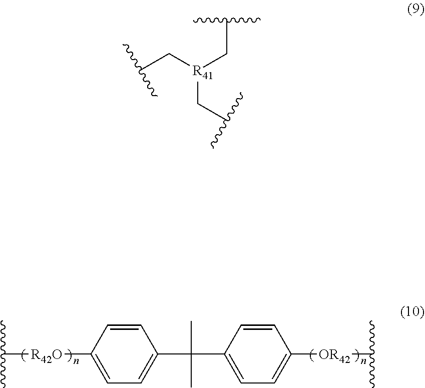

In the formulas (9) and (10), R₄₁ and R₄₂ each independently represent an alkyl group having 1 to 5 carbon atoms, an aryl group, or an aralkyl group, and each n independently represents an integer of 0 to 10.

The epoxy resin composition of the present embodiment may contain a plurality of aminimide compounds represented by the formula (1), (2) and/or (3) as the curing agent. By containing a plurality of aminimide compounds, curing temperature control or viscosity control is attained, an effect of improving characteristics is obtained. The epoxy resin composition of the present embodiment may contain a plurality of aminimide compounds that are represented by the same formula but differ in structure among the aminimide compounds represented by the formulas (1) to (3).

In the case of using an aminimide composition containing a plurality of aminimide compounds as the heteroatom-containing curing agent (B), the aminimide composition may be obtained by mixing the plurality of aminimide compounds, or may obtained by producing the plurality of aminimide compounds at the same time by a method for producing an aminimide compound mentioned later.

### <Methods for Producing Aminimide Compound and Aminimide Composition>

The method for producing the aminimide compound as the heteroatom-containing curing agent (B) for use in the epoxy resin composition of the present embodiment is not particularly limited as long as the method produces the aminimide compound having any of the structures of the formulas (1) to (3) mentioned above. The method for producing the aminimide composition includes a method of mixing a plurality of aminimide compounds obtained by a method mentioned later, and a method of producing a plurality of amine compounds at the same time to obtain a mixture.

One example of the method for producing the aminimide compound includes a method containing a reaction step of reacting a carboxylic acid ester compound (B-A), a hydrazine compound (B-B), and a glycidyl ether compound (B-C). Hereinafter, the method for producing the aminimide compound will be described. In the description below, each of the compounds (B-A) to (B-C) is also referred to as a “component (B-A), etc.”

Examples of the ester compound (B-A) include, but are not limited to, monocarboxylic acid ester compounds, dicarboxylic acid ester compounds, and cyclic esters.

Examples of the monocarboxylic acid ester compound include, but are not limited to, methyl lactate, ethyl lactate, methyl mandelate, methyl acetate, methyl propionate, ethyl propionate, methyl butyrate, methyl isobutyrate, methyl valerate, methyl isovalerate, methyl pivalate, methyl heptanoate, methyl octanoate, methyl acrylate, methyl methacrylate, methyl crotonate, methyl isocrotonate, methyl benzoylformate, 2-methoxybenzoylmethyl, 3-methoxybenzoylmethyl, 4-methoxybenzoylmethyl, 2-ethoxybenzoylmethyl, and 4-t-butoxybenzoylmethyl. Ethyl esters, propyl esters, and the like may be used instead of these compounds.

Examples of the dicarboxylic acid ester compound include, but are not limited to, dimethyl oxalate, dimethyl malonate, dimethyl succinate, dimethyl tartrate, dimethyl glutarate, dimethyl adipate, dimethyl pimelate, dimethyl suberate, dimethyl azelate, dimethyl sebacate, dimethyl maleate, dimethyl fumarate, dimethyl itaconate, dimethyl phthalate, dimethyl isophthalate, dimethyl terephthalate, dimethyl 1,3-acetonedicarboxylate, and diethyl 1,3-acetonedicarboxylate. Alternatively, for example, cyclic esters may be used instead of these compounds.

Examples of the cyclic esters include, but are not limited to, α-acetolactone, β-propiolactone, γ-butyrolactone, δ-valerolactone, γ-valerolactone, and ε-caprolactone. Diethyl esters, dipropyl esters, and the like may be used instead of these compounds.

Among them, the ester compound (B-A) is preferably ethyl lactate, methyl mandelate, methyl acetate, methyl propionate, ethyl propionate, methyl butyrate, methyl isobutyrate, methyl valerate, methyl isovalerate, methyl pivalatemethyl acrylate, methyl methacrylate, methyl crotonate, methyl isocrotonate, methyl benzoylformate, dimethyl oxalate, dimethyl malonate, dimethyl succinate, dimethyl tartrate, dimethyl glutarate, dimethyl adipate, dimethyl pimelate, dimethyl suberate, dimethyl azelate, dimethyl maleate, dimethyl fumarate, dimethyl phthalate, dimethyl isophthalate, dimethyl terephthalate, dimethyl 1,3-acetonedicarboxylate, and diethyl 1,3-acetonedicarboxylate, γ-butyrolactone, δ-valerolactone, or γ-valerolactone from the viewpoint of the curability and liquefication of the aminimide compound as the curing agent (B).

Among them, the ester compound (B-A) is more preferably ethyl lactate, ethyl propionate, methyl mandelate, methyl benzoylformate, dimethyl oxalate, dimethyl malonate, dimethyl succinate, dimethyl glutarate, dimethyl adipate, γ-butyrolactone, γ-valerolactone, δ-valerolactone, or diethyl 1,3-acetonedicarboxylate from the viewpoint of the ease of obtainment.

These ester compounds (B-A) may each be used singly or may be used in combination of two or more thereof.

Examples of the hydrazine compound (B-B) include, but are not limited to, dimethylhydrazine, diethylhydrazine, methylethylhydrazine, methylpropylhydrazine, methylbutylhydrazine, methylpentylhydrazine, methylhexylhydrazine, ethylpropylhydrazine, ethylbutylhydrazine, ethylpentylhydrazine, ethylhexylhydrazine, dipropylhydrazine, dibutylhydrazine, dipentylhydrazine, dihexylhydrazine, methylphenylhydrazine, ethylphenylhydrazine, methyltolylhydrazine, ethyltolylhydrazine, diphenylhydrazine, benzylphenylhydrazine, dibenzylhydrazine, dinitrophenylhydrazine, 1-aminopiperidine, N-aminohomopiperidine, 1-amino-2,6-dimethylpiperidine, 1-aminopyrrolidine, 1-amino-2-methylpyrrolidine, 1-amino-2-phenylpyrrolidine, and 1-aminomorpholine.

Among them, the hydrazine compound (B-B) is preferably dimethylhydrazine, dibenzylhydrazine, 1-aminopiperidine, 1-aminopyrrolidine, or 1-aminomorpholine from the viewpoint of curability and liquefication. Among them, dibenzylhydrazine and 1-aminopiperidine are more preferred from the viewpoint of the ease of obtainment and safety.

These hydrazine compounds (B-B) may each be used singly or may be used in combination of two or more thereof.

The glycidyl ether compound (B-C) is not limited, and, for example, a monofunctional monoglycidyl ether compound or a difunctional or higher polyglycidyl ether compound can be used.

Examples of the monoglycidyl ether compound include, but are not limited to, methyl glycidyl ether, ethyl glycidyl ether, n-butyl glycidyl ether, t-butyl glycidyl ether, 2-ethylhexyl glycidyl ether, dodecyl glycidyl ether, higher alcohol glycidyl ether, allyl glycidyl ether, phenyl glycidyl ether, cresyl glycidyl ether, o-phenylphenol glycidyl ether, benzyl glycidyl ether, biphenylyl glycidyl ether, 4-t-butylphenyl glycidyl ether, t-butyldimethylsilyl glycidyl ether, and 3-[diethoxy(methyl)silyl]propyl glycidyl ether.

Examples of the polyglycidyl ether compound include, but are not limited to: aliphatic polyglycidyl ether such as ethylene glycol diglycidyl ether, diethylene glycol diglycidyl ether, triethylene glycol diglycidyl ether, polyethylene glycol diglycidyl ether, propylene glycol diglycidyl ether, dipropylene glycol diglycidyl ether, tripropylene glycol diglycidyl ether, polypropylene glycol diglycidyl ether, neopentyl glycol diglycidyl ether, butanediol glycidyl ether, hexanediol glycidyl ether, trimethylolpropane polyglycidyl ether, glycerin polyglycidyl ether, diglycerin polyglycidyl ether, polyglycerin polyglycidyl ether, and sorbitol polyglycidyl ether; alicyclic polyglycidyl ether compounds such as bisphenol A-type diglycidyl ether, bisphenol F-type diglycidyl ether, bisphenol S-type diglycidyl ether, ethylene oxide-added bisphenol A-type diglycidyl ether, propylene oxide-added bisphenol A-type diglycidyl ether, and hydrogenation products of their condensates; and aromatic polyglycidyl ether compounds such as resorcinol diglycidyl ether.

Among them, the glycidyl ether compound (B-C) is preferably methyl glycidyl ether, ethyl glycidyl ether, n-butyl glycidyl ether, t-butyl glycidyl ether, 2-ethylhexyl glycidyl ether, allyl glycidyl ether, phenyl glycidyl ether, t-butyldimethylsilyl glycidyl ether, ethylene glycol diglycidyl ether, diethylene glycol diglycidyl ether, neopentyl glycol diglycidyl ether, butanediol glycidyl ether, hexanediol glycidyl ether, trimethylolpropane polyglycidyl ether, bisphenol A-type diglycidyl ether, bisphenol F-type diglycidyl ether, ethylene oxide-added bisphenol A-type diglycidyl ether, and propylene oxide-added bisphenol A-type diglycidyl ether from the viewpoint of the curability and liquefication of the aminimide compound as the curing agent (B).

Among them, the glycidyl ether compound (B-C) is more preferably n-butyl glycidyl ether, t-butyl glycidyl ether, 2-ethylhexyl glycidyl ether, allyl glycidyl ether, trimethylolpropane polyglycidyl ether, ethylene oxide-added bisphenol A-type diglycidyl ether, butanediol glycidyl ether, hexanediol glycidyl ether, or propylene oxide-added bisphenol A-type diglycidyl ether from the viewpoint of the ease of obtainment and Tg of a cured product.

These glycidyl ether compounds (B-C) may each be used singly or may be used in combination of two or more thereof.

The amounts of the ester compound (B-A), the hydrazine compound (B-B), and the glycidyl ether compound (B-C) added to the reaction system for preparing the aminimide compound can be set on the basis of the molar ratios of functional groups. The ester group of the ester compound (B-A) is preferably 0.8 mol to 3.0 mol, more preferably 0.9 mol to 2.8 mol, further preferably 0.95 mol to 2.5 mol, based on mol of the primary amine of the hydrazine compound (B-B). The glycidyl group of the glycidyl ether compound (B-C) is preferably 0.8 mol to 2.0 mol, more preferably 0.9 mol to 1.5 mol, further preferably 0.95 mol to 1.4 mol, based on mol of the primary amine of the hydrazine compound (B-B).

The aminimide composition containing aminimide compounds represented by the formula (1) and the formula (3) can be produced at the same time by controlling the amount of the glycidyl group of the glycidyl ether compound (B-C) added based on mol of the primary amine of the hydrazine compound (B-B). Specifically, the glycidyl group of the glycidyl ether compound (B-C) is preferably 0.1 mol to 3.0 mol, more preferably 0.3 mol to 2.0 mol, further preferably 0.5 mol to 1.0 mol, based on mol of the primary amine of the hydrazine compound (B-B).

In the methods for producing the aminimide compound and the aminimide composition mentioned above, a solvent may be used from the viewpoint that the reaction progresses homogeneously.

The solvent is not particularly limited as long as the solvent does not react with the components (B-A) to (B-C). Examples thereof include: alcohols such as methanol, ethanol, 1-propanol, 2-propanol, butanol, and t-butyl alcohol; and ethers such as tetrahydrofuran and diethyl ether.

The reaction temperature of the components (B-A) to (B-C) is preferably 10° C. or higher and 100° C. or lower, more preferably 40° C. or higher and 90° C. or lower. When the reaction temperature is 10° C. or higher, the progression of the reaction is accelerated and the purity of the resulting aminimide compound tends to be more improved. When the reaction temperature is 90° C. or lower, the purity of the aminimide compound tends to be more improved because the polymerization reaction between glycidyl ether compounds (B-C) can be efficiently suppressed.

The reaction time of the components (B-A) to (B-C) is preferably 1 hour or longer and 168 hours or shorter, more preferably 1 hour or longer and 96 hours or shorter, further preferably 1 hour or longer and 48 hours or shorter.

After the completion of reaction, the obtained reaction product can be purified by a purification method known in the art, such as washing, extraction, recrystallization, or column chromatography. For example, a reaction solution of the product dissolved in an organic solvent is washed with water. Then, an organic layer is heated under ordinary pressure or reduced pressure so that unreacted starting materials or the organic solvent can be removed from the reaction solution to recover an aminimide compound. Alternatively, the obtained reaction product can be purified by column chromatography to recover an aminimide compound.

The solvent for use in washing mentioned above is not particularly limited as long as the solvent can dissolve residues of starting materials. 1-Hexane, 1-pentane, and cyclohexane are preferred from the viewpoint of yield, purity, and the ease of removal.

The organic solvent for use in extraction mentioned above is not particularly limited as long as the solvent can dissolve the aminimide compound of interest. Ethyl acetate, dichloromethane, chloroform, carbon tetrachloride, toluene, diethyl ether, and methyl isobutyl ketone are preferred, and ethyl acetate, chloroform, toluene, and methyl isobutyl ketone are more preferably used, from the viewpoint of yield, purity, and the ease of removal.

A packing agent known in the art, such as alumina or silica gel, can be used in column chromatography. One or a mixture of developing solvents known in the art, such as ethyl acetate, dichloromethane, chloroform, carbon tetrachloride, tetrahydrofuran, diethyl ether, acetone, methyl isobutyl ketone, acetonitrile, methanol, ethanol, and isopropanol, can be used.

<Heteroatom-Containing Curing Agent (B) Other than Aminimide Compound>

In the epoxy resin composition of the present embodiment, a heteroatom-containing curing agent other than the aminimide compound mentioned above may be used as the heteroatom-containing curing agent (B) as long as the molecular weight of the curing agent and the number of heteroatoms in its structure fall within specific ranges. Examples of such a heteroatom-containing curing agent include, but are not limited to: amine-based curing agents such as imidazoles, aliphatic amines, aromatic amines, and polyamide resin; amide-based curing agents; acid anhydride-based curing agents such as acid anhydride; phenol-based curing agents such as phenols, polyhydric phenol compounds and their modification products; and BF3-amine complexes and guanidine derivatives.

These curing agents may each be used singly or may be used in combination of two or more thereof.

### <Content of Heteroatom-Containing Curing Agent (B)>

In the epoxy resin composition of the present embodiment, the total content of the heteroatom-containing curing agent (B) is preferably 1 part by mass to 50 parts by mass, more preferably 1 part by mass to 40 parts by mass, further preferably 1 part by mass to 30 parts by mass, based on 100 parts by mass in total of the epoxy resin (A).

When the total content of the heteroatom-containing curing agent (B) falls within the range mentioned above, more favorable physical properties of curing tend to be obtained while the curing reaction of the epoxy resin composition of the present embodiment sufficiently progresses.

In the case of using the aminimide compound mentioned above as the curing agent in the epoxy resin composition of the present embodiment, the total content of the aminimide compound is preferably 1 part by mass to 50 parts by mass, more preferably 1 part by mass to 40 parts by mass, further preferably 1 part by mass to 30 parts by mass, based on 100 parts by mass in total of the epoxy resin (A), as in the above. When the total content of the aminimide compound according to the present embodiment falls within the range mentioned above, more favorable physical properties of curing tend to be obtained while the curing reaction of the epoxy resin composition of the present embodiment sufficiently progresses.

In the case of using the aminimide compound according to the present embodiment as a curing accelerator for the heteroatom-containing curing agent (B) other than the aminimide compound, the total content of the aminimide compound according to the present embodiment is preferably 0.1 parts by mass to 30 parts by mass, more preferably 0.5 parts by mass to 20 parts by mass, further preferably 1 part by mass to 15 parts by mass, based on 100 parts by mass in total of the epoxy resin (A). When the total content of the aminimide compound according to the present embodiment falls within the range mentioned above, more favorable physical properties of curing tend to be obtained while the curing reaction of the epoxy resin composition of the present embodiment sufficiently progresses, owing to the aminimide compound according to the present embodiment that functions as a curing catalyst for the heteroatom-containing curing agent (B) other than the aminimide compound.

In the epoxy resin composition of the present embodiment, the heteroatom-containing curing agent (B) can be used in combination with an additional curing agent other than the curing agent (B). In this respect, the heteroatom-containing curing agent (B) may function as a curing accelerator for the additional curing agent. In the case of using the heteroatom-containing curing agent (B) in combination with the additional curing agent, the total content of the heteroatom-containing curing agent (B) is preferably 0.1 parts by mass or more and 30 parts by mass or less, more preferably 0.5 parts by mass or more and 20 parts by mass or less, further preferably 1 part by mass or more and 15 parts by mass or less, based on 100 parts by mass in total of the epoxy resin (A). When the content of the heteroatom-containing curing agent (B) for combined use with the additional curing agent falls within the range mentioned above, more favorable physical properties of curing tend to be obtained while the curing reaction of the epoxy resin composition of the present embodiment sufficiently progresses, owing to the heteroatom-containing curing agent (B) that functions as a curing catalyst for the additional curing agent.

Examples of the additional curing agent, other than the curing agent (B), which may be used in combination with the heteroatom-containing curing agent (B) include, but are not limited to: amine-based curing agents such as imidazoles, aliphatic amines, aromatic amines, and polyamide resin; amide-based curing agents; acid anhydride-based curing agents such as acid anhydride; phenol-based curing agents such as phenols, polyhydric phenol compounds and their modification products; and BF3-amine complexes and guanidine derivatives, none of which satisfy the molecular weight α and the ratio α/β.

These additional curing agents may each be used singly or may be used in combination of two or more thereof.

In the epoxy resin composition of the present embodiment, the total content of the heteroatom-containing curing agent (B) in the epoxy resin composition is preferably 0.4% by mass to 50% by mass from the viewpoint of achieving both reactivity and stability. The total content is more preferably 2.0% by mass or more, further preferably 8.1% by mass or more, still further preferably 9.0% by mass or more, from the viewpoint of reactivity. The total amount is more preferably 40% by mass or less, further preferably 25% by mass or less, still further preferably 22% by mass or less, from the viewpoint of storage stability.

### (Inorganic Filler (C))

The epoxy resin composition of the present embodiment may optionally contain an inorganic filler. Use of the inorganic filler can enhance low linear thermal expansion of the resulting cured product. Examples of the inorganic filler include, but are not particularly limited to, fused silica, crystalline silica, alumina, talc, silicon nitride, and aluminum nitride.

In the epoxy resin composition of the present embodiment, the content of the inorganic filler (C) is preferably more than 5% by mass and 98% by mass or less, more preferably 10% by mass or more and 95% by mass or less, further preferably 10% by mass or more and 90% by mass or less, still further preferably 10% by mass or more and 87% by mass or less, based on the whole epoxy resin composition of the present embodiment. When the content of the inorganic filler (C) falls within the range mentioned above, the resulting cured product tends to have low linear thermal expansion.

### (Stabilizer (D))

The epoxy resin composition of the present embodiment may optionally contain a stabilizer (D). Examples of the stabilizer (D) include, but are not limited to, monocarboxylic acid ester compounds, dicarboxylic acid ester compounds, and cyclic lactone compounds.

For example, a compound represented by the following formula (A) or (B) can be used as the stabilizer.

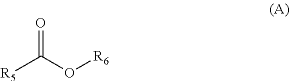

In the formula (A), R₅ and R₆ each independently represent a hydrogen atom, or a monovalent or n-valent organic group having 1 to 15 carbon atoms and optionally having a hydroxy group, a carbonyl group, an ester bond, or an ether bond; and n represents an integer of 2 to 3.

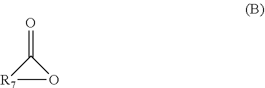

In the formula (B), R₇ represents a monovalent or n-valent organic group having 1 to 15 carbon atoms and optionally having a hydroxy group, a carbonyl group, an ester bond, or an ether bond; and n represents an integer of 2 to 3.

In the formula (A), R₅ and R₆ each independently represent a hydrogen atom, or a “monovalent or n-valent organic group having 1 to 15 carbon atoms and optionally having a hydroxy group, a carbonyl group, or an ester bond”.

In the formula (B), R₇ represents a “monovalent or n-valent organic group having 1 to 15 carbon atoms and optionally having a hydroxy group, a carbonyl group, an ester bond, or an ether bond”.

Examples of these organic groups include, but are not limited to, “hydrocarbon groups”, “groups in which a hydrogen atom bonded to a carbon atom in a hydrocarbon group is replaced with a hydroxy group or a carbonyl group”, and “groups in which one or some carbon atoms constituting a hydrocarbon group are replaced with an ester bond or an ether bond”, as in R₁ in the formula (1) mentioned above.

Examples of the monocarboxylic acid ester compound as the stabilizer (D) include, but are not limited to, methyl lactate, ethyl lactate, methyl mandelate, methyl acetate, methyl propionate, methyl butyrate, methyl isobutyrate, methyl valerate, methyl isovalerate, methyl pivalate, methyl heptanoate, methyl octanoate, methyl acrylate, methyl methacrylate, methyl crotonate, methyl isocrotonate, methyl benzoylformate, 2-methoxybenzoylmethyl, 3-methoxybenzoylmethyl, 4-methoxybenzoylmethyl, 2-ethoxybenzoylmethyl, and 4-t-butoxybenzoylmethyl. Ethyl esters, propyl esters, and the like may be used instead of these compounds.

Examples of the dicarboxylic acid ester compound as the stabilizer (D) include, but are not limited to, dimethyl oxalate, dimethyl malonate, dimethyl succinate, dimethyl tartrate, dimethyl glutarate, dimethyl adipate, dimethyl pimelate, dimethyl suberate, dimethyl azelate, dimethyl sebacate, dimethyl maleate, dimethyl fumarate, dimethyl itaconate, dimethyl phthalate, dimethyl isophthalate, dimethyl terephthalate, dimethyl 1,3-acetonedicarboxylate, and diethyl 1,3-acetonedicarboxylate.

Examples of the cyclic ester compound as the stabilizer (D) include, but are not limited to, α-acetolactone, β-propiolactone, γ-butyrolactone, δ-valerolactone, γ-valerolactone, and ε-caprolactone. Diethyl esters, dipropyl esters, and the like may be used instead of these compounds.

In the epoxy resin composition of the present embodiment, an additional stabilizer other than the stabilizer mentioned above may be used. Examples of the additional stabilizer include, but are not limited to, acidic compounds such as Lewis acid compounds containing boron, aluminum, gallium, indium, or the like, carboxylic acid, phenols, and organic acids.

In the epoxy resin composition of the present embodiment, the content of the stabilizer (D) is preferably 1 part by mass or more and 30 parts by mass or less, more preferably 1 part by mass or more and 20 parts by mass or less, further preferably 1 part by mass or more and 10 parts by mass or less, based on 100 parts by mass of the epoxy resin (A). When the content of the stabilizer (D) falls within the range mentioned above, the resulting epoxy resin composition tends to be excellent in storage stability.

### (Other Blending Agents)

The epoxy resin composition of the present embodiment may optionally further contain an additional blending agent such as a curing accelerator, a flame retardant, a silane coupling agent, a mold release agent, or a pigment. A suitable one can be appropriately selected as such an additional blending agent as long as the effects of the present embodiment are obtained. Examples of the flame retardant include, but are not limited to, halides, phosphorus atom-containing compounds, nitrogen atom-containing compounds, and inorganic flame retardant compounds.

### [Preparation of Epoxy Resin Composition and Cured Product]

The cured product of the present embodiment is a cured product obtained by curing the epoxy resin composition of the present embodiment.

The cured product of the present embodiment is obtained, for example, by thermally curing the epoxy resin composition mentioned above by a conventional method known in the art. The cured product of the present embodiment can be obtained by, for example, the following method.

First, the epoxy resin (A) and the heteroatom-containing curing agent (B) mentioned above, and further, an optional inorganic filler (C), stabilizer (D), curing accelerator, and/or blending agent, etc. are sufficiently mixed until homogeneous using an extruder, a kneader, a roll, or the like to obtain an epoxy resin composition. Then, the epoxy resin composition can be molded by casting or using a transfer molding machine, a compression molding machine, an injection molding machine, or the like, and further heated under conditions of approximately 80 to 200° C. and approximately 2 to 10 hours to obtain the cured product of the present embodiment.

Alternatively, the cured product of the present embodiment can be obtained by, for example, the following method.

First, the epoxy resin composition mentioned above is dissolved in a solvent such as toluene, xylene, acetone, methyl ethyl ketone, or methyl isobutyl ketone to obtain a solution. A base material such as glass fibers, carbon fibers, polyester fibers, polyamide fibers, alumina fibers, or paper is impregnated with the obtained solution, and dried by heating to obtain a prepreg. Next, the obtained prepreg can be molded by heat press to obtain a cured product.

### Application

The epoxy resin composition of the present embodiment and the cured product obtained therefrom can be used in various applications in which epoxy resin is used as a material. The epoxy resin composition and the cured product are particularly useful in applications such as encapsulants (encapsulants formed from the cured product of the present embodiment), encapsulants for semiconductors, adhesives (adhesives containing the epoxy resin composition of the present embodiment), print substrate materials, coating materials, and composite materials. Among them, the epoxy resin composition and the cured product are suitably used in semiconductor encapsulants such as underfills and moldings, conductive adhesives such as anisotropically conductive films (ACFs), printed circuit boards such as solder resists and coverlay films, and composite materials such as prepregs prepared by the impregnation of glass fibers, carbon fibers, or the like.

### (Electronic Member)

The cured product of the present embodiment mentioned above can be used in electronic members. Examples of the electronic member include, but are not limited to, semiconductor encapsulants such as underfills and moldings, conductive adhesives such as ACF, printed circuit boards such as solder resists and coverlay films, and composite materials such as prepregs prepared by the impregnation of glass fibers, carbon fibers, or the like.

### EXAMPLES

Next, the present invention will be described still more specifically with reference to Synthesis Examples, Examples, and Comparative Examples. However, the present invention is not limited by these examples by any means.

In the description below, the terms “parts” and “%” are based on mass unless otherwise specified.

### [Synthesis of Heteroatom-Containing Curing Agent (B)]

An aminimide compound was synthesized as the heteroatom-containing curing agent (B). The molecular weight (molecular weight α) of this aminimide compound and number β of heteroatoms in the aminimide compound were measured by ESI-MS to confirm that the aminimide compound of interest was able to be synthesized.

### Synthesis Example 1

7.08 g (0.060 mol) of ethyl lactate, 6.00 g (0.060 mol) of 1-aminopiperidine, and 7.19 g (0.030 mol) of 1,6-hexanediol diglycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 15.85 g (yield: 92.2%) of pale yellow liquid compound A (compound A given below). Since a measurement value of ESI-MS was 575.36 (H⁺), the corresponding description in the table was adopted to the molecular weight α.

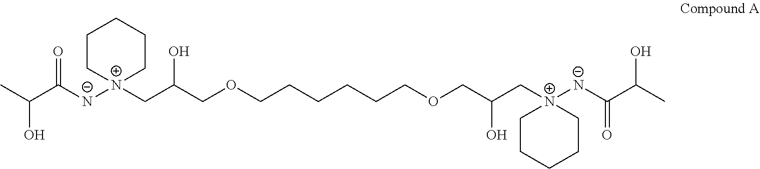 [SMILES: CC(O)C(=O)[N-][N+]1(CC(O)COCCCCCCOCC(O)C[N+]2([N-]C(=O)C(C)O)CCCCC2)CCCCC1]

### Synthesis Example 2

6.12 g (0.060 mol) of ethyl propionate, 6.00 g (0.060 mol) of 1-aminopiperidine, and 7.19 g (0.030 mol) of 1,6-hexanediol diglycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 14.03 g (yield: 86.4%) of pale yellow liquid compound B (compound B given below). Since a measurement value of ESI-MS was 543.42 (H⁺), the corresponding description in the table was adopted to the molecular weight α.

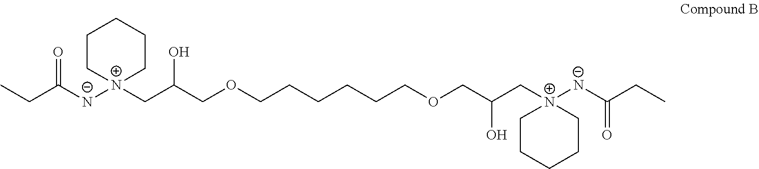 [SMILES: CCC(=O)[N-][N+]1(CC(O)COCCCCCCOCC(O)C[N+]2([N-]C(=O)CC)CCCCC2)CCCCC1]

### Synthesis Example 3

5.16 g (0.060 mol) of γ-butyrolactone, 6.00 g (0.060 mol) of 1-aminopiperidine, and 7.19 g (0.030 mol) of 1,6-hexanediol diglycidyl ether were mixed. This solution was reacted with stirring at 80° C. for 4 hours. The obtained reaction solution was concentrated under reduced pressure at 60° C. so that unreacted starting materials were distilled off to obtain a liquid product. Unreacted starting material residues were removed from this product by repetitive washing with hexane. This organic layer was concentrated under reduced pressure at 60° C. again to obtain 15.57 g (yield: 86.2%) of pale yellow liquid compound C (compound C given below). Since a measurement value of ESI-MS was 603.43 (H⁺), the corresponding description in the table was adopted to the molecular weight α.

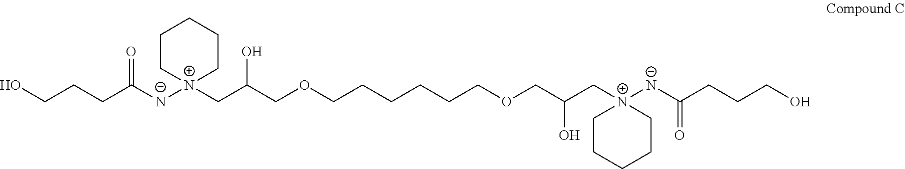 [SMILES: O=C(CCCO)[N-][N+]1(CC(O)COCCCCCCOCC(O)C[N+]2([N-]C(=O)CCCO)CCCCC2)CCCCC1]

### Synthesis Example 4

6.00 g (0.060 mol) of γ-valerolactone, 6.00 g (0.060 mol) of 1-aminopiperidine, and 7.19 g (0.030 mol) of 1,6-hexanediol diglycidyl ether were mixed. This solution was reacted with stirring at 80° C. for 4 hours. The obtained reaction solution was concentrated under reduced pressure at 60° C. so that unreacted starting materials were distilled off to obtain a liquid product. Unreacted starting material residues were removed from this product by repetitive washing with hexane. This organic layer was concentrated under reduced pressure at 60° C. again to obtain 16.08 g (yield: 85.1%) of pale yellow liquid compound D (compound D given below). Since a measurement value of ESI-MS was 631.46 (H⁺), the corresponding description in the table was adopted to the molecular weight α.

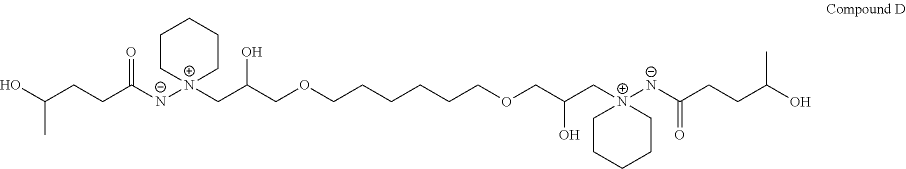 [SMILES: CC(O)CCC(=O)[N-][N+]1(CC(O)COCCCCCCOCC(O)C[N+]2([N-]C(=O)CCC(C)O)CCCCC2)CCCCC1]

### Synthesis Example 5

7.08 g (0.060 mol) of ethyl lactate, 6.00 g (0.060 mol) of 1-aminopiperidine, and 10.36 g (0.030 mol) of bisphenol A-type epoxy resin (EXA850CRP, DIC Corp.) were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 18.64 g (yield: 90.6%) of pale yellow compound E (compound E given below). Since a measurement value of ESI-MS was 685.44 (H⁺), the corresponding description in the table was adopted to the molecular weight α.

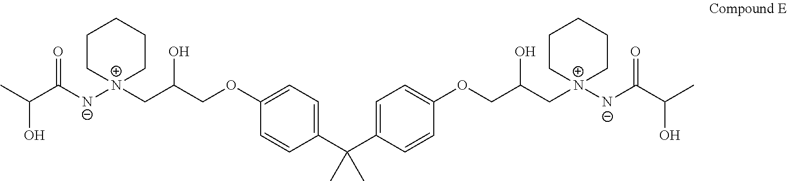 [SMILES: CC(O)C(=O)[N-][N+]1(CC(O)COc2ccc(C(C)(C)c3ccc(OCC(O)C[N+]4([N-]C(=O)C(C)O)CCCCC4)cc3)cc2)CCCCC1]

### Synthesis Example 6

7.08 g (0.060 mol) of ethyl lactate, 6.00 g (0.060 mol) of 1-aminopiperidine, and 5.81 g (0.020 mol) of a trifunctional glycidyl amine compound (jER630, Mitsubishi Chemical Corp.) were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 14.18 g (yield: 89.1%) of pale yellow compound F (compound F given below). Since a measurement value of ESI-MS was 794.45 (H⁺), the corresponding description in the table was adopted to the molecular weight α.

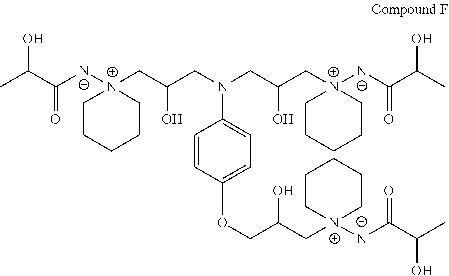 [SMILES: CC(O)C(=O)[N-][N+]1(CC(O)COc2ccc(N(CC(O)C[N+]3([N-]C(=O)C(C)O)CCCCC3)CC(O)C[N+]3([N-]C(=O)C(C)O)CCCCC3)cc2)CCCCC1]

### Synthesis Example 7

9.83 g (0.060 mol) of methyl benzoylformate, 6.00 g (0.060 mol) of 1-aminopiperidine, and 11.16 g (0.060 mol) of 2-ethylhexyl glycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 23.82 g (yield: 94.9%) of pale yellow liquid compound G (compound G given below). Since a measurement value of ESI-MS was 419.31 (H⁺), the corresponding description in the table was adopted to the molecular weight α.

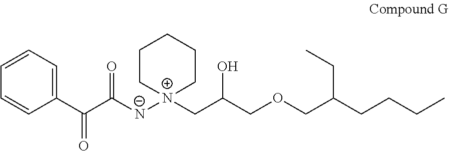 [SMILES: CCCCC(CC)COCC(O)C[N+]1([N-]C(=O)C(=O)c2ccccc2)CCCCC1]

### Synthesis Example 8

6.12 g (0.060 mol) of ethyl propionate, 6.00 g (0.060 mol) of 1-aminopiperidine, and 7.80 g (0.060 mol) of n-butyl glycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 14.94 g (yield: 94.9%) of pale yellow liquid compound H (compound H given below). Since a measurement value of ESI-MS was 287.27 (H⁺), the corresponding description in the table was adopted to the molecular weight α.

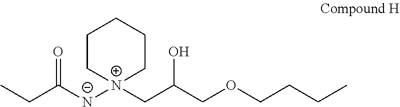 [SMILES: CCCCOCC(O)C[N+]1([N-]C(=O)CC)CCCCC1]

### Synthesis Example 9

8.75 g (0.060 mol) of dimethyl succinate, 6.00 g (0.060 mol) of 1-aminopiperidine, and 7.19 g (0.030 mol) of 1,6-hexanediol diglycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 17.62 g (yield: 89.3%) of pale yellow liquid compound I (compound I given below). Since a measurement value of ESI-MS was 659.36 (H⁺), the corresponding description in the table was adopted to the molecular weight α.

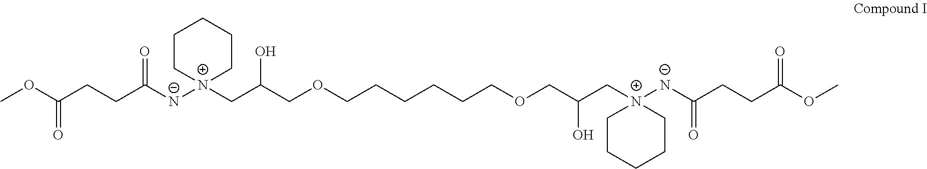

### Synthesis Example 10

6.96 g (0.060 mol) of ethyl isobutyrate, 6.00 g (0.060 mol) of 1-aminopiperidine, and 31.57 g (0.030 mol) of poly(ethylene glycol) diglycidyl ether (n9) were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 22.49 g (yield: 89.5%) of pale yellow liquid compound J (compound J given below). Since a measurement value of ESI-MS was 839.57 (H⁺), the corresponding description in the table was adopted to the molecular weight α.

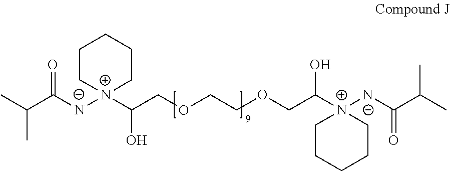

### Synthesis Example 11

6.12 g (0.060 mol) of ethyl propionate, 6.00 g (0.060 mol) of 1-aminopiperidine, and 31.57 g (0.030 mol) of poly(ethylene glycol) diglycidyl ether (n9) were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 24.29 g (yield: 85.4%) of pale yellow liquid compound K (compound K given below). Since a measurement value of ESI-MS was 811.51 (H⁺), the corresponding description in the table was adopted to the molecular weight α.

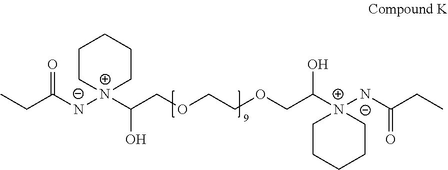

### Synthesis Example 12

6.12 g (0.060 mol) of ethyl propionate, 6.00 g (0.060 mol) of 1-aminopiperidine, and 18.33 g (0.030 mol) of poly(ethylene glycol) diglycidyl ether (n4) were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 14.82 g (yield: 83.7%) of pale yellow liquid compound L (compound L given below). Since a measurement value of ESI-MS was 591.38 (H⁺), the corresponding description in the table was adopted to the molecular weight α.

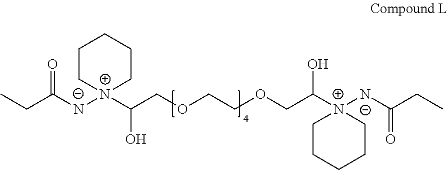

### Synthesis Example 13

6.96 g (0.060 mol) of ethyl isobutyrate, 6.00 g (0.060 mol) of 1-aminopiperidine, and 18.69 g (0.030 mol) of BisF-type epoxy resin were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 17.00 g (yield: 86.9%) of pale yellow liquid compound M (compound M given below). Since a measurement value of ESI-MS was 653.43 (H⁺), the corresponding description in the table was adopted to the molecular weight α.

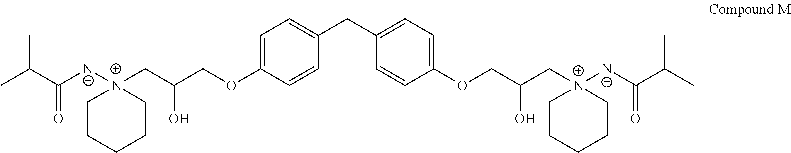 [SMILES: CC(C)C(=O)[N-][N+]1(CC(O)COc2ccc(Cc3ccc(OCC(O)C[N+]4([N-]C(=O)C(C)C)CCCCC4)cc3)cc2)CCCCC1]

### Synthesis Example 14

6.12 g (0.060 mol) of ethyl propionate, 6.00 g (0.060 mol) of 1-aminopiperidine, and 18.69 g (0.030 mol) of BisF-type epoxy resin were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 15.35 g (yield: 82.0%) of pale yellow liquid compound N (compound N given below). Since a measurement value of ESI-MS was 625.40 (H⁺), the corresponding description in the table was adopted to the molecular weight α.

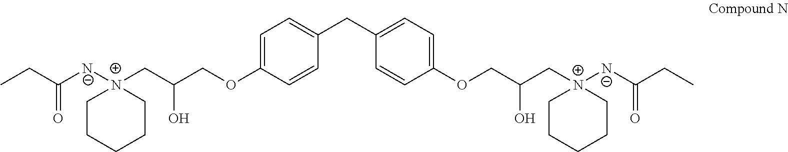 [SMILES: CCC(=O)[N-][N+]1(CC(O)COc2ccc(Cc3ccc(OCC(O)C[N+]4([N-]C(=O)CC)CCCCC4)cc3)cc2)CCCCC1]

### Synthesis Example 15

6.96 g (0.060 mol) of ethyl isobutyrate, 6.00 g (0.060 mol) of 1-aminopiperidine, and 16.29 g (0.030 mol) of naphthalene-type epoxy resin were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 15.90 g (yield: 86.6%) of pale yellow liquid compound O (compound O given below). Since a measurement value of ESI-MS was 613.43 (H⁺), the corresponding description in the table was adopted to the molecular weight α.

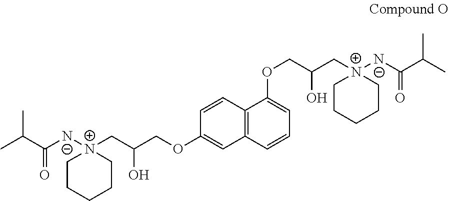 [SMILES: CC(C)C(=O)[N-][N+]1(CC(O)COc2ccc3c(OCC(O)C[N+]4([N-]C(=O)C(C)C)CCCCC4)cccc3c2)CCCCC1]

### Synthesis Example 16

6.12 g (0.060 mol) of ethyl propionate, 6.00 g (0.060 mol) of 1-aminopiperidine, and 16.29 g (0.030 mol) of naphthalene-type epoxy resin were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 15.38 g (yield: 87.8%) of pale yellow liquid compound P (compound P given below). Since a measurement value of ESI-MS was 585.38 (H⁺), the corresponding description in the table was adopted to the molecular weight α.

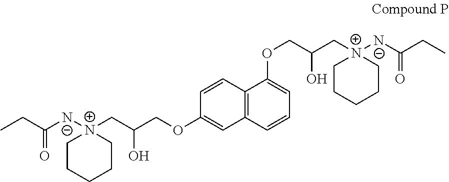 [SMILES: CCC(=O)[N-][N+]1(CC(O)COc2ccc3c(OCC(O)C[N+]4([N-]C(=O)CC)CCCCC4)cccc3c2)CCCCC1]

### Synthesis Example 17

6.12 g (0.060 mol) of ethyl propionate, 6.00 g (0.060 mol) of 1-aminopiperidine, and 9.82 g (0.030 mol) of cresyl glycidyl ether were mixed. This solution was reacted with stirring at 80° C. for 4 hours. The obtained reaction solution was concentrated under reduced pressure at 60° C. so that secondarily produced alcohols and unreacted starting materials were distilled off to obtain a liquid product. Unreacted starting material residues were removed from this product by repetitive washing with hexane. This organic layer was concentrated under reduced pressure at 60° C. again to obtain 8.13 g (yield: 84.8%) of pale yellow liquid compound Q (compound Q given below). Since a measurement value of ESI-MS was 321.42 (H⁺), the corresponding description in the table was adopted to the molecular weight α.

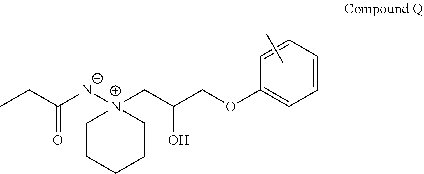

Next, an epoxy resin composition containing the compound of each Synthesis Example was prepared in accordance with Examples mentioned later. Then, characteristics mentioned later were each measured as to the obtained epoxy resin composition.

### [(1) Lap-Shear Strength]

Test pieces were prepared in accordance with JIS K6850 using epoxy resin compositions of Examples and Comparative Examples mentioned later. The adherend used was a 25 mm wide×100 mm long×1.6 mm thick adherend (cold-rolled copper plate) in accordance with JIS C3141. Each uncured test piece was placed in a small high-temperature chamber “ST-110B2” manufactured by ESPEC Corp., the internal temperature of which was stable at 150° C., and heated for 2 hours to obtain a lap-shear strength measurement test piece. 2 hours later, the structure (lap-shear strength measurement test piece) was taken out of the small high-temperature chamber, left in an environment of room temperature, and cooled to room temperature. After cooling to room temperature, “AGX-5kNX” manufactured by Shimadzu Corp. was used with a load cell of 5 kN and at a rate of 5 mm/min to measure the maximum load where the adhesion surface of the test piece was ruptured so that the test piece was separated. A value obtained by dividing the maximum load at which the separation occurred by the adhesion area was regarded as lap-shear strength. The “adhesion” was evaluated from the obtained lap-shear strength according to the following criteria.

### [Criteria]

⊚: Lap-shear strength A was 16.0 MPa<A.
◯: Lap-shear strength A was 13.5 MPa<A≤16.0 MPa.
Δ: Lap-shear strength A was 10.0 MPa<A≤13.5 MPa.
X: Lap-shear strength A was A≤10 MPa.

### [(2) Storage Stability]

Each of epoxy resin compositions obtained in Examples and Comparative Examples mentioned later was preserved at 25° C. for 72 hours, and a viscosity was measured before and after preservation using a type BM viscometer (25° C.).

The ratio of the viscosity of the epoxy resin composition after preservation to the viscosity of the epoxy resin composition before preservation (viscosity increase ratio) (=the viscosity after preservation/the viscosity before preservation) was calculated, and the “storage stability (storage stability at room temperature)” was evaluated according to the following criteria.
⊚: The viscosity increase ratio was less than 1.75-fold.
◯: The viscosity increase ratio was 1.75-fold or more and less than 3-fold.
X: The viscosity increase ratio was 3-fold or more.

### [(3) Linear Thermal Expansion]

Each of epoxy resin compositions obtained in Examples and Comparative Examples mentioned later was placed in a small high-temperature chamber “ST-110B2” manufactured by ESPEC Corp., the internal temperature of which was stable at 150° C., and heated for 2 hours to obtain a cured product for TMA (thermomechanical analysis) measurement. 2 hours later, the structure was taken out of the small high-temperature chamber, left in an environment of room temperature, and cooled to room temperature. After cooling to room temperature, “Q400” manufactured by TA Instruments was used to carry out TMA measurement at a temperature increase rate of 5° C./min. A value obtained by dividing a slope that connected two points of 30° C. and 45° C. by the test piece length was regarded as a “coefficient of thermal expansion”. The linear thermal expansion was evaluated according to the following criteria.
⊚: The coefficient of thermal expansion was less than 50 ppm/° C.
◯: The coefficient of thermal expansion was 50 ppm/° C. or more and less than 70 ppm/° C.
Δ: The coefficient of thermal expansion was 70 ppm/° C. or more and less than 100 ppm/° C.
X: The coefficient of thermal expansion was 100 ppm/° C. or more or not measurable.

### Example 1

10 g of the epoxy resin (“EXA-830CRP” manufactured by DIC Corp.) and 3.0 g of compound A were placed in a plastic stirring container and mixed by stirring using a rotation/revolution mixer (“ARE-310” manufactured by Thinky Corp.) to prepare an epoxy resin composition. The “adhesion” was evaluated by the method (1) for evaluating lap-shear strength mentioned above, the “storage stability at room temperature” was evaluated by the method (2) for evaluating storage stability mentioned above, and the “linear thermal expansion” was evaluated by the method (3) for evaluating linear thermal expansion mentioned above.

### Example 2

An epoxy resin composition was prepared and evaluated for its adhesion, storage stability at room temperature, and linear thermal expansion in the same manner as in Example 1 except that the compound A was changed to compound B.

### Example 3

An epoxy resin composition was prepared and evaluated for its adhesion, storage stability at room temperature, and linear thermal expansion in the same manner as in Example 1 except that the compound A was changed to compound C.

### Example 4

An epoxy resin composition was prepared and evaluated for its adhesion, storage stability at room temperature, and linear thermal expansion in the same manner as in Example 1 except that the compound A was changed to compound D.

### Example 5

An epoxy resin composition was prepared and evaluated for its adhesion, storage stability at room temperature, and linear thermal expansion in the same manner as in Example 1 except that the compound A was changed to compound E. The storage stability was not measurable due to a highly viscous formulation and was therefore indicated by “-” in the table below.

### Example 6

An epoxy resin composition was prepared and evaluated for its adhesion, storage stability at room temperature, and linear thermal expansion in the same manner as in Example 1 except that the compound A was changed to compound F. The storage stability was not measurable due to a highly viscous formulation and was therefore indicated by “-” in the table below.

### Example 7

An epoxy resin composition was prepared and evaluated for its adhesion, storage stability at room temperature, and linear thermal expansion in the same manner as in Example 1 except that the compound A was changed to compound G.

### Example 8

An epoxy resin composition was prepared and evaluated for its adhesion, storage stability at room temperature, and linear thermal expansion in the same manner as in Example 1 except that the compound A was changed to compound H.

### Example 9

An epoxy resin composition was prepared and evaluated for its adhesion, storage stability at room temperature, and linear thermal expansion in the same manner as in Example 1 except that the compound A was changed to compound I.

### Example 10

10 g of the epoxy resin (“EXA-830CRP” manufactured by DIC Corp.) and 0.7 g of a silica filler (“SO-E2” manufactured by Admatechs Co., Ltd.) were kneaded using three rolls (BR-150HCV manufactured by AIMEX Corp.), then placed together with 3.0 g of compound A in a plastic stirring container, and mixed by stirring using a rotation/revolution mixer (“ARE-310” manufactured by Thinky Corp.) to prepare an epoxy resin composition. The “adhesion” was evaluated by the method (1) for evaluating lap-shear strength mentioned above, the “storage stability at room temperature” was evaluated by the method (2) for evaluating storage stability mentioned above, and the “linear thermal expansion” was evaluated by the method (3) for evaluating linear thermal expansion mentioned above.

### Example 11

An epoxy resin composition was prepared and evaluated for its adhesion, storage stability at room temperature, and linear thermal expansion in the same manner as in Example 10 except that the amount of the silica filler added was 1.4 g.

### Example 12

An epoxy resin composition was prepared and evaluated for its adhesion, storage stability at room temperature, and linear thermal expansion in the same manner as in Example 10 except that the amount of the silica filler added was 13.0 g.

### Example 13

An epoxy resin composition was prepared and evaluated for its adhesion, storage stability at room temperature, and linear thermal expansion in the same manner as in Example 1 except that 0.7 g of ethyl propionate was added as a stabilizer.

### Example 14

An epoxy resin composition was prepared and evaluated for its adhesion, storage stability at room temperature, and linear thermal expansion in the same manner as in Example 1 except that 1.4 g of ethyl propionate was added as a stabilizer.

### Example 15

An epoxy resin composition was prepared and evaluated for its adhesion, storage stability at room temperature, and linear thermal expansion in the same manner as in Example 1 except that 0.7 g of γ-butyrolactone was added as a stabilizer.

### Example 16

An epoxy resin composition was prepared and evaluated for its adhesion, storage stability at room temperature, and linear thermal expansion in the same manner as in Example 1 except that 1.4 g of γ-butyrolactone was added as a stabilizer.

### Example 17

An epoxy resin composition was prepared and evaluated for its adhesion, storage stability at room temperature, and linear thermal expansion in the same manner as in Example 1 except that 1.4 g of ethyl lactate was added as a stabilizer.

### Example 18

An epoxy resin composition was prepared and evaluated for its adhesion, storage stability at room temperature, and linear thermal expansion in the same manner as in Example 1 except that 1.4 g of dimethyl succinate was added as a stabilizer.

### Example 19

An epoxy resin composition was prepared and evaluated for its adhesion, storage stability at room temperature, and linear thermal expansion in the same manner as in Example 1 except that the amount of the compound A added was changed to 1.0 g.

### Example 20

An epoxy resin composition was prepared and evaluated for its adhesion, storage stability at room temperature, and linear thermal expansion in the same manner as in Example 1 except that the epoxy resin used was changed to 5.0 g of epoxy resin A (“EXA-830CRP” manufactured by DIC Corp.) and 5.0 g of epoxy resin B (“jER630” manufactured by Mitsubishi Chemical Corp.).

### Example 21

An epoxy resin composition was prepared and evaluated for its adhesion, storage stability at room temperature, and linear thermal expansion in the same manner as in Example 1 except that the epoxy resin used was changed to 5.0 g of epoxy resin A (“EXA-830CRP” manufactured by DIC Corp.) and 5.0 g of epoxy resin C (“HP4032D” manufactured by DIC Corp.).

### Example 22

An epoxy resin composition was prepared and evaluated for its adhesion, storage stability at room temperature, and linear thermal expansion in the same manner as in Example 1 except that the epoxy resin used was changed to 4.0 g of epoxy resin A (“EXA-830CRP” manufactured by DIC Corp.), 4.0 g of epoxy resin B (“jER630” manufactured by Mitsubishi Chemical Corp.), 1.0 g of epoxy resin D (“jER1032H60” manufactured by Mitsubishi Chemical Corp.), and 1.0 g of epoxy resin F (“CDMDG” manufactured by Showa Denko Karenz).

### Example 23

An epoxy resin composition was prepared and evaluated for its adhesion, storage stability at room temperature, and linear thermal expansion in the same manner as in Example 1 except that the epoxy resin used was changed to 4.0 g of epoxy resin A (“EXA-830CRP” manufactured by DIC Corp.), 4.0 g of epoxy resin B (“jER630” manufactured by Mitsubishi Chemical Corp.), 1.0 g of epoxy resin D (“jER1032H60” manufactured by Mitsubishi Chemical Corp.), and 1.0 g of epoxy resin G (“YX8000” manufactured by Mitsubishi Chemical Corp.).

### Example 24

An epoxy resin composition was prepared and evaluated for its adhesion, storage stability at room temperature, and linear thermal expansion in the same manner as in Example 1 except that the epoxy resin used was changed to 4.0 g of epoxy resin A (“EXA-830CRP” manufactured by DIC Corp.), 4.0 g of epoxy resin B (“jER630” manufactured by Mitsubishi Chemical Corp.), 1.0 g of epoxy resin D (“jER1032H60” manufactured by Mitsubishi Chemical Corp.), and 1.0 g of epoxy resin H (“YED216D” manufactured by Mitsubishi Chemical Corp.).

### Example 25

An epoxy resin composition was prepared and evaluated for its adhesion, storage stability at room temperature, and linear thermal expansion in the same manner as in Example 1 except that the epoxy resin used was changed to 4.0 g of epoxy resin A (“EXA-830CRP” manufactured by DIC Corp.), 4.0 g of epoxy resin B (“jER630” manufactured by Mitsubishi Chemical Corp.), 1.0 g of epoxy resin E (“YX4000H” manufactured by Mitsubishi Chemical Corp.), and 1.0 g of epoxy resin I (“PETG” manufactured by Showa Denko Karenz).

### Example 26

An epoxy resin composition was prepared and evaluated for its adhesion, storage stability at room temperature, and linear thermal expansion in the same manner as in Example 1 except that the epoxy resin used was changed to 4.0 g of epoxy resin A (“EXA-830CRP” manufactured by DIC Corp.), 4.0 g of epoxy resin B (“jER630” manufactured by Mitsubishi Chemical Corp.), 1.0 g of epoxy resin E (“YX4000H” manufactured by Mitsubishi Chemical Corp.), and 1.0 g of epoxy resin J (“EX-321L” manufactured by Nagase Chemtex Corp.).

### Example 27

An epoxy resin composition was prepared and evaluated for its adhesion, storage stability at room temperature, and linear thermal expansion in the same manner as in Example 1 except that the compound A was changed to compound J.

### Example 28

An epoxy resin composition was prepared and evaluated for its adhesion, storage stability at room temperature, and linear thermal expansion in the same manner as in Example 1 except that the compound A was changed to compound K.

### Example 29

An epoxy resin composition was prepared and evaluated for its adhesion, storage stability at room temperature, and linear thermal expansion in the same manner as in Example 10 except that: the compound A was changed to compound K; the silica filler was changed to “SE2200-SEJ” manufactured by Admatechs Co., Ltd.; and the amount of the silica filler added was 19.5 g.

### Example 30

An epoxy resin composition was prepared and evaluated for its adhesion, storage stability at room temperature, and linear thermal expansion in the same manner as in Example 24 except that the silica filler was changed to “SE205-SEJ” manufactured by Admatechs Co., Ltd.

### Example 31

An epoxy resin composition was prepared and evaluated for its adhesion, storage stability at room temperature, and linear thermal expansion in the same manner as in Example 24 except that the silica filler was changed to “SE203-SEJ” manufactured by Admatechs Co., Ltd.

### Example 32

An epoxy resin composition was prepared and evaluated for its adhesion, storage stability at room temperature, and linear thermal expansion in the same manner as in Example 24 except that the silica filler was changed to “SE1050-SET” manufactured by Admatechs Co., Ltd.

### Example 33

An epoxy resin composition was prepared and evaluated for its adhesion, storage stability at room temperature, and linear thermal expansion in the same manner as in Example 24 except that the amount of the silica filler added was 30.0 g.

### Example 34

An epoxy resin composition was prepared and evaluated for its adhesion, storage stability at room temperature, and linear thermal expansion in the same manner as in Example 24 except that the amount of the silica filler added was 39.0 g.

### Example 35

An epoxy resin composition was prepared and evaluated for its adhesion, storage stability at room temperature, and linear thermal expansion in the same manner as in Example 24 except that the silica filler used was 31.0 g of “SE2200-SEJ” manufactured by Admatechs Co., Ltd. and 46.0 g of “FB-5D” manufactured by Denka Co., Ltd.

### Example 36

An epoxy resin composition was prepared and evaluated for its adhesion, storage stability at room temperature, and linear thermal expansion in the same manner as in Example 24 except that: the silica filler used was 36.0 g of “SE2200-SEJ” manufactured by Admatechs Co., Ltd. and 57.0 g of “FB-5D” manufactured by Denka Co., Ltd.; and 1.4 g of γ-butyrolactone was added as a stabilizer.

### Example 37

An epoxy resin composition was prepared and evaluated for its adhesion, storage stability at room temperature, and linear thermal expansion in the same manner as in Example 24 except that: the epoxy resin used was changed to 6.0 g of epoxy resin A (“EXA-830CRP” manufactured by DIC Corp.) and 4.0 g of epoxy resin H (“YED216D” manufactured by Mitsubishi Chemical Corp.); the silica filler used was 49.0 g of “SE2200-SEJ” manufactured by Admatechs Co., Ltd. and 81.0 g of “FB-5D” manufactured by Denka Co., Ltd.; and 1.4 g of γ-butyrolactone was added as a stabilizer.

### Example 38

An epoxy resin composition was prepared and evaluated for its adhesion, storage stability at room temperature, and linear thermal expansion in the same manner as in Example 24 except that: the epoxy resin used was changed to 0.6 g of epoxy resin A (“EXA-830CRP” manufactured by DIC Corp.) and 0.4 g of epoxy resin H (“YED216D” manufactured by Mitsubishi Chemical Corp.); the silica filler used was 27.4 g of a magnetic powder of NdFeB alloy having an average particle size of 100 μm; and 0.14 g of γ-butyrolactone was added as a stabilizer.

### Example 39

An epoxy resin composition was prepared and evaluated for its adhesion, storage stability at room temperature, and linear thermal expansion in the same manner as in Example 24 except that: the epoxy resin used was changed to 0.6 g of epoxy resin A (“EXA-830CRP” manufactured by DIC Corp.) and 0.4 g of epoxy resin H (“YED216D” manufactured by Mitsubishi Chemical Corp.); the silica filler used was 70.6 g of a magnetic powder of NdFeB alloy having an average particle size of 100 μm; and 0.14 g of γ-butyrolactone was added as a stabilizer.

### Example 40

An epoxy resin composition was prepared and evaluated for its adhesion, storage stability at room temperature, and linear thermal expansion in the same manner as in Example 1 except that the compound A was changed to compound L.

### Example 41

An epoxy resin composition was prepared and evaluated for its adhesion, storage stability at room temperature, and linear thermal expansion in the same manner as in Example 1 except that the compound A was changed to compound M.

### Example 42

An epoxy resin composition was prepared and evaluated for its adhesion, storage stability at room temperature, and linear thermal expansion in the same manner as in Example 1 except that the compound A was changed to compound N.

### Example 43

An epoxy resin composition was prepared and evaluated for its adhesion, storage stability at room temperature, and linear thermal expansion in the same manner as in Example 1 except that the compound A was changed to compound 0.

### Example 44

An epoxy resin composition was prepared and evaluated for its adhesion, storage stability at room temperature, and linear thermal expansion in the same manner as in Example 1 except that the compound A was changed to compound P.

### Example 45

An epoxy resin composition was prepared and evaluated for its adhesion, storage stability at room temperature, and linear thermal expansion in the same manner as in Example 1 except that the compound A was changed to compound Q.

### Example 46

An epoxy resin composition was prepared and evaluated for its adhesion, storage stability at room temperature, and linear thermal expansion in the same manner as in Example 1 except that the compound A was changed to 2.25 g of the compound A and 0.75 g of compound E.

### Example 47

An epoxy resin composition was prepared and evaluated for its adhesion, storage stability at room temperature, and linear thermal expansion in the same manner as in Example 1 except that the compound A was changed to 2.0 g of compound B and 1.0 g of compound E.

### Example 48

An epoxy resin composition was prepared and evaluated for its adhesion, storage stability at room temperature, and linear thermal expansion in the same manner as in Example 1 except that the compound A was changed to 1.0 g of compound B, 1.0 g of compound F and 1.0 g of compound N.

### Example 49

An epoxy resin composition was prepared and evaluated for its adhesion, storage stability at room temperature, and linear thermal expansion in the same manner as in Example 1 except that the compound A was changed to 2.25 g of compound J and 0.75 g of compound M.

### Example 50

An epoxy resin composition was prepared and evaluated for its adhesion, storage stability at room temperature, and linear thermal expansion in the same manner as in Example 1 except that the compound A was changed to 2.0 g of compound J and 1.0 g of compound Q.

### Example 51

An epoxy resin composition was prepared and evaluated for its adhesion, storage stability at room temperature, and linear thermal expansion in the same manner as in Example 1 except that the compound A was changed to 2.25 g of compound K and 0.75 g of compound N.

### Example 52

An epoxy resin composition was prepared and evaluated for its adhesion, storage stability at room temperature, and linear thermal expansion in the same manner as in Example 1 except that the compound A was changed to 2.5 g of compound L and 0.5 g of compound N.

### Example 53

An epoxy resin composition was prepared and evaluated for its adhesion, storage stability at room temperature, and linear thermal expansion in the same manner as in Example 1 except that the compound A was changed to 2.0 g of compound L and 1.0 g of compound Q.

### Example 54

An epoxy resin composition was prepared and evaluated for its adhesion, storage stability at room temperature, and linear thermal expansion in the same manner as in Example 1 except that the compound A was changed to 2.25 g of compound K and 0.75 g of compound P.

### Example 55

An epoxy resin composition was prepared and evaluated for its adhesion, storage stability at room temperature, and linear thermal expansion in the same manner as in Example 1 except that the compound A was changed to 2.25 g of compound K and 0.75 g of compound Q.

### Example 56

An epoxy resin composition was prepared and evaluated for its adhesion, storage stability at room temperature, and linear thermal expansion in the same manner as in Example 1 except that the compound A was changed to 0.975 g of the compound A, 0.325 g of compound E and 2.6 g of curing agent A (4,4′-diamino-3,3′-diethyldiphenylmethane).

### Example 57

An epoxy resin composition was prepared and evaluated for its adhesion, storage stability at room temperature, and linear thermal expansion in the same manner as in Example 10 except that: the compound A was changed to 0.975 g of the compound A, 0.325 g of compound E and 2.6 g of curing agent A (4,4′-diamino-3,3′-diethyldiphenylmethane); and the amount of the silica filler added was 13.0 g.

### Example 58

An epoxy resin composition was prepared and evaluated for its adhesion, storage stability at room temperature, and linear thermal expansion in the same manner as in Example 10 except that: the compound A was changed to 0.975 g of the compound J, 0.325 g of compound M and 2.6 g of curing agent A (4,4′-diamino-3,3′-diethyldiphenylmethane); and the amount of the silica filler added was 13.0 g.

### Example 59

An epoxy resin composition was prepared and evaluated for its adhesion, storage stability at room temperature, and linear thermal expansion in the same manner as in Example 10 except that: the compound A was changed to 0.975 g of the compound K, 0.325 g of compound N and 2.6 g of curing agent A (4,4′-diamino-3,3′-diethyldiphenylmethane); and the amount of the silica filler added was 13.0 g.

### Example 60

An epoxy resin composition was prepared and evaluated for its adhesion, storage stability at room temperature, and linear thermal expansion in the same manner as in Example 10 except that: the compound A was changed to 0.693 g of compound A, 0.231 g of compound E and 1.8 g of curing agent B (liquid aromatic amine having a diaminodiphenylmethane skeleton); and the amount of the silica filler added was 13.0 g.

### Example 61

An epoxy resin composition was prepared and evaluated for its adhesion, storage stability at room temperature, and linear thermal expansion in the same manner as in Example 10 except that: the compound A was changed to 0.693 g of compound J, 0.231 g of compound M and 1.8 g of curing agent B (liquid aromatic amine having a diaminodiphenylmethane skeleton); and the amount of the silica filler added was 13.0 g.

### Example 62

An epoxy resin composition was prepared and evaluated for its adhesion, storage stability at room temperature, and linear thermal expansion in the same manner as in Example 10 except that: the compound A was changed to 0.693 g of compound K, 0.231 g of compound N and 1.8 g of curing agent B (liquid aromatic amine having a diaminodiphenylmethane skeleton); and the amount of the silica filler added was 13.0 g.

### Comparative Example 1

An epoxy resin composition was prepared and evaluated for its adhesion, storage stability at room temperature, and linear thermal expansion in the same manner as in Example 1 except that the compound A was changed to 3.6 g of curing agent A (4,4′-diamino-3,3′-diethyldiphenylmethane).

### Comparative Example 2

An epoxy resin composition was prepared and evaluated for its adhesion, storage stability at room temperature, and linear thermal expansion in the same manner as in Example 1 except that the compound A was changed to 2.8 g of curing agent B (liquid aromatic amine having a diaminodiphenylmethane skeleton).

### Comparative Example 3

An epoxy resin composition was prepared and evaluated for its adhesion, storage stability at room temperature, and linear thermal expansion in the same manner as in Example 1 except that: the compound A was changed to 9.3 g of curing agent C (“HN5500” manufactured by Showa Denko Materials Co., Ltd.); and 0.05 g of 2E4MZ (2-ethyl-4-methylimidazole) was further added as a curing accelerator.

The curing agent C is acid anhydride and has molecular weight α of 168.

### Comparative Example 4

An epoxy resin composition was prepared and evaluated for its adhesion, storage stability at room temperature, and linear thermal expansion in the same manner as in Example 1 except that the compound A was changed to 0.8 g of curing agent D (dicyandiamide (DICY)).

The composition and the evaluation results in each of Examples and Comparative Examples are shown in the tables below.

TABLE 1

| Composition of epoxy resin | | Example | Example | Example | Example | Example | Example |
|---|---|---|---|---|---|---|---|
| composition (parts by mass) | | 1 | 2 | 3 | 4 | 5 | 6 |
| Epoxy resin | EXA830CRP | 10 | 10 | 10 | 10 | 10 | 10 |
| | jER630 | | | | | | |
| | HP 4032D | | | | | | |
| | jER1032H60 | | | | | | |
| | YX4000H | | | | | | |
| | CDMDG | | | | | | |
| | YX8000 | | | | | | |
| | YED216D | | | | | | |
| | PETG | | | | | | |
| | EX-321L | | | | | | |
| Curing agent | Compound A | 3 | | | | | |
| | Compound B | | 3 | | | | |
| | Compound C | | | 3 | | | |
| | Compound D | | | | 3 | | |
| | Compound E | | | | | 3 | |
| | Compound F | | | | | | 3 |
| | Compound G | | | | | | |
| | Compound H | | | | | | |
| | Compound I | | | | | | |
| | Curing agent A | | | | | | |
| | Curing agent B | | | | | | |
| | Curing agent C | | | | | | |
| | Curing agent D | | | | | | |
| Curing accelerator | 2E4MZ | | | | | | |
| Inorganic filler | SO-E2 | | | | | | |
| Stabilizer | Ethyl propionate | | | | | | |
| | γ-Butyrolactone | | | | | | |
| | Ethyl lactate | | | | | | |
| | Dimethyl succinate | | | | | | |
| Molecular weight α of curing agent | | 574 | 542 | 603 | 631 | 687 | 797 |
| α/β value of curing agent | | 48 | 54 | 50 | 53 | 57 | 47 |
| Lap-shear strength (Cu) (adhesion) | | ⊚ | ⊚ | ⊚ | ⊚ | ⊚ | ⊚ |
| Stability after 25° C. × 72 h (storage stability | | ◯ | ◯ | ◯ | ◯ | — | — |
| at room temperature) | | | | | | | |
| TMA | CTE < Tg(ppm/° C.) (linear | Δ | Δ | Δ | Δ | Δ | Δ |
| | thermal expansion) | | | | | | |
| Composition of epoxy resin | | Example | Example | Example | Example | Example | Example |
| composition (parts by mass) | | 7 | 8 | 9 | 10 | 11 | 12 |
| Epoxy resin | EXA830CRP | 10 | 10 | 10 | 10 | 10 | 10 |
| | jER630 | | | | | | |
| | HP 4032D | | | | | | |
| | jER1032H60 | | | | | | |
| | YX4000H | | | | | | |
| | CDMDG | | | | | | |
| | YX8000 | | | | | | |
| | YED216D | | | | | | |
| | PETG | | | | | | |
| | EX-321L | | | | | | |
| Curing agent | Compound A | | | | 3 | 3 | 3 |
| | Compound B | | | | | | |
| | Compound C | | | | | | |
| | Compound D | | | | | | |
| | Compound E | | | | | | |
| | Compound F | | | | | | |
| | Compound G | 3 | | | | | |
| | Compound H | | 3 | | | | |
| | Compound I | | | 3 | | | |
| | Curing agent A | | | | | | |
| | Curing agent B | | | | | | |
| | Curing agent C | | | | | | |
| | Curing agent D | | | | | | |
| Curing accelerator | 2E4MZ | | | | | | |
| Inorganic filler | SO-E2 | | | | 0.7 | 1.4 | 13 |
| Stabilizer | Ethyl propionate | | | | | | |
| | γ-Butyrolactone | | | | | | |
| | Ethyl lactate | | | | | | |
| | Dimethyl succinate | | | | | | |
| Molecular weight α of curing agent | | 419 | 286 | 659 | 574 | 574 | 574 |
| α/β value of curing agent | | 70 | 57 | 47 | 48 | 48 | 48 |
| Lap-shear strength (Cu) (adhesion) | | ◯ | ◯ | ◯ | ⊚ | ⊚ | ◯ |
| Stability after 25° C. × 72 h (storage stability | | ◯ | ◯ | ◯ | ◯ | ◯ | ⊚ |
| at room temperature) | | | | | | | |
| TMA | CTE < Tg(ppm/° C.) (linear | Δ | Δ | Δ | ◯ | ◯ | ⊚ |
| | thermal expansion) | | | | | | |

TABLE 2

| Composition of epoxy resin | | Example | Example | Example | Example | Example | Example | Example |
|---|---|---|---|---|---|---|---|---|
| composition (parts by mass) | | 13 | 14 | 15 | 16 | 17 | 18 | 19 |
| Epoxy resin | EXA830CRP | 10 | 10 | 10 | 10 | 10 | 10 | 10 |
| | jER630 | | | | | | | |
| | HP4032D | | | | | | | |
| | jER1032H60 | | | | | | | |
| | YX4000H | | | | | | | |
| | CDMDG | | | | | | | |
| | YX8000 | | | | | | | |
| | YED216D | | | | | | | |
| | PETG | | | | | | | |
| | EX-321L | | | | | | | |
| Curing agent | Compound A | 3 | 3 | 3 | 3 | 3 | 3 | 1 |
| | Compound B | | | | | | | |
| | Compound C | | | | | | | |
| | Compound D | | | | | | | |
| | Compound E | | | | | | | |
| | Compound F | | | | | | | |
| | Compound G | | | | | | | |
| | Compound H | | | | | | | |
| | Compound I | | | | | | | |
| | Curing agent A | | | | | | | |
| | Curing agent B | | | | | | | |
| | Curing agent C | | | | | | | |
| | Curing agent D | | | | | | | |
| Curing | 2E4MZ | | | | | | | |
| accelerator | | | | | | | | |
| Inorganic | SO-E2 | | | | | | | |
| filler | | | | | | | | |
| Stabilizer | Ethyl propionate | 0.7 | 1.4 | | | | | |
| | γ-Butyrolactone | | | 0.7 | 1.4 | | | |
| | Ethyl lactate | | | | | 1.4 | | |
| | Dimethyl succinate | | | | | | 1.4 | |
| Molecular weight α of curing agent | | 574 | 574 | 574 | 574 | 574 | 574 | 574 |
| α/β value of curing agent | | 48 | 48 | 48 | 48 | 48 | 48 | 48 |
| Lap-shear strength (Cu) (adhesion) | | ⊚ | ⊚ | ⊚ | ⊚ | ⊚ | ⊚ | ⊚ |
| Stability after 25° C. × 72 h (storage | | ⊚ | ⊚ | ⊚ | ⊚ | ⊚ | ⊚ | ⊚ |
| stability at room temperature) | | | | | | | | |
| TMA | CTE < Tg(ppm/° C.) | Δ | Δ | Δ | Δ | Δ | Δ | Δ |
| | (linear thermal | | | | | | | |
| | expansion) | | | | | | | |

TABLE 3

| Composition of epoxy resin | | Example | Example | Example | Example | Example | Example | Example |
|---|---|---|---|---|---|---|---|---|
| composition (parts by mass) | | 20 | 21 | 22 | 23 | 24 | 25 | 26 |
| Epoxy resin | EXA830CRP | 5 | 5 | 4 | 4 | 4 | 4 | 4 |
| | jER630 | 5 | | 4 | 4 | 4 | 4 | 4 |
| | HP4032D | | 5 | | | | | |
| | jER1032H60 | | | 1 | 1 | 1 | | |
| | YX4000H | | | | | | 1 | 1 |
| | CDMDG | | | 1 | | | | |
| | YX8000 | | | | 1 | | | |
| | YED216D | | | | | 1 | | |
| | PETG | | | | | | 1 | |
| | EX-321L | | | | | | | 1 |
| Curing agent | Compound A | 3 | 3 | 3 | 3 | 3 | 3 | 3 |
| | Compound B | | | | | | | |
| | Compound C | | | | | | | |
| | Compound D | | | | | | | |
| | Compound E | | | | | | | |
| | Compound F | | | | | | | |
| | Compound G | | | | | | | |
| | Compound H | | | | | | | |
| | Compound I | | | | | | | |
| | Curing agent A | | | | | | | |
| | Curing agent B | | | | | | | |
| | Curing agent C | | | | | | | |
| | Curing agent D | | | | | | | |
| Curing | 2E4MZ | | | | | | | |
| accelerator | | | | | | | | |
| Inorganic | SO-E2 | | | | | | | |
| filler | | | | | | | | |
| Stabilizer | Ethyl propionate | | | | | | | |
| | γ-Butyrolactone | | | | | | | |
| | Ethyl lactate | | | | | | | |
| | Dimethyl succinate | | | | | | | |
| Molecular weight α of curing | | 574 | 574 | 574 | 574 | 574 | 574 | 574 |
| agent | | | | | | | | |
| α/β value of curing agent | | 48 | 48 | 48 | 48 | 48 | 48 | 48 |
| Lap-shear strength (Cu) | | ⊚ | ⊚ | ⊚ | ⊚ | ⊚ | ⊚ | ⊚ |
| (adhesion) | | | | | | | | |
| Stability after 25° C. × 72 h | | ◯ | ◯ | ◯ | ◯ | ◯ | ◯ | ◯ |
| (storage stability at room | | | | | | | | |
| temperature) | | | | | | | | |
| TMA | CTE < Tg(ppm/° C.) | Δ | Δ | Δ | Δ | Δ | Δ | Δ |
| | (linear thermal | | | | | | | |
| | expansion) | | | | | | | |

TABLE 4

| Composition of epoxy resin | | Example | Example | Example | Example | Example | Example | Example | Example | Example |
|---|---|---|---|---|---|---|---|---|---|---|
| composition (parts by mass) | | 27 | 28 | 29 | 30 | 31 | 32 | 33 | 34 | 35 |
| Epoxy resin | EXA830CRP | 10 | 10 | 10 | 10 | 10 | 10 | 10 | 10 | 10 |
| | YED216 | | | | | | | | | |
| Curing agent | Compound A | | | | | | | | | |
| | Compound B | | | | | | | | | |
| | Compound C | | | | | | | | | |
| | Compound D | | | | | | | | | |
| | Compound E | | | | | | | | | |
| | Compound F | | | | | | | | | |
| | Compound G | | | | | | | | | |
| | Compound H | | | | | | | | | |
| | Compound I | | | | | | | | | |
| | Compound J | 3 | | | | | | | | |
| | Compound K | | 3 | 3 | 3 | 3 | 3 | 3 | 3 | 3 |
| | Compound L | | | | | | | | | |
| | Compound M | | | | | | | | | |
| | Compound N | | | | | | | | | |
| | Compound O | | | | | | | | | |
| | Compound P | | | | | | | | | |
| | Compound Q | | | | | | | | | |
| | Curing agent A | | | | | | | | | |
| | Curing agent B | | | | | | | | | |
| | Curing agent C | | | | | | | | | |
| | Curing agent D | | | | | | | | | |
| Curing | 2E4MZ | | | | | | | | | |
| accelerator | | | | | | | | | | |
| Inorganic | SO-E2 | | | | | | | | | |
| filler | SE2200-SEJ | | | 19.5 | | | | 30 | 39 | 31 |
| | SE205-SEJ | | | | 19.5 | | | | | |
| | SE203-SEJ | | | | | 19.5 | | | | |
| | SE1050-SET | | | | | | 19.5 | | | |
| | FB-5D | | | | | | | | | 46 |
| | NdFeB powder | | | | | | | | | |
| Stabilizer | Ethyl propionate | | | | | | | | | |
| | γ-Butyrolactone | | | | | | | | | |
| | Ethyl lactate | | | | | | | | | |
| | Dimethyl succinate | | | | | | | | | |
| Molecular weight α of curing | | 839 | 811 | 811 | 811 | 811 | 811 | 811 | 811 | 811 |
| agent | | | | | | | | | | |
| α/β value of curing agent | | 47 | 45 | 45 | 45 | 45 | 45 | 45 | 45 | 45 |
| Lap-shear strength (Cu) | | ⊚ | ⊚ | ◯ | ◯ | ◯ | ◯ | ◯ | ◯ | ◯ |
| (adhesion) | | | | | | | | | | |
| Stability after 25° C. × 72 h | | ◯ | ◯ | ⊚ | ⊚ | ⊚ | ⊚ | ⊚ | ⊚ | ⊚ |
| (storage stability at room | | | | | | | | | | |
| temperature) | | | | | | | | | | |
| TMA | CTE < Tg(ppm/° C.) | Δ | Δ | ⊚ | ⊚ | ⊚ | ⊚ | ⊚ | ⊚ | ⊚ |
| | (linear thermal | | | | | | | | | |
| | expansion) | | | | | | | | | |

TABLE 5

| Composition of epoxy resin | | Example | Example | Example | Example | Example | Example | Example | Example | Example |
|---|---|---|---|---|---|---|---|---|---|---|
| composition (parts by mass) | | 36 | 37 | 38 | 39 | 40 | 41 | 42 | 43 | 44 |
| Epoxy resin | EXA830CRP | 10 | 6 | 0.6 | 0.6 | 10 | 10 | 10 | 10 | 10 |
| | YED216 | | 4 | 0.4 | 0.4 | | | | | |
| Curing agent | Compound A | | | | | | | | | |
| | Compound B | | | | | | | | | |
| | Compound C | | | | | | | | | |
| | Compound D | | | | | | | | | |
| | Compound E | | | | | | | | | |
| | Compound F | | | | | | | | | |
| | Compound G | | | | | | | | | |
| | Compound H | | | | | | | | | |
| | Compound I | | | | | | | | | |
| | Compound J | | | | | | | | | |
| | Compound K | 3 | 3 | 0.3 | 0.3 | | | | | |
| | Compound L | | | | | 3 | | | | |
| | Compound M | | | | | | 3 | | | |
| | Compound N | | | | | | | 3 | | |
| | Compound O | | | | | | | | 3 | |
| | Compound P | | | | | | | | | 3 |
| | Compound Q | | | | | | | | | |
| | Curing agent A | | | | | | | | | |
| | Curing agent B | | | | | | | | | |
| | Curing agent C | | | | | | | | | |
| | Curing agent D | | | | | | | | | |
| Curing | 2E4MZ | | | | | | | | | |
| accelerator | | | | | | | | | | |
| Inorganic | SO-E2 | | | | | | | | | |
| filler | SE2200-SEJ | 36 | 49 | | | | | | | |
| | SE205-SEJ | | | | | | | | | |
| | SE203-SEJ | | | | | | | | | |
| | SE1050-SET | | | | | | | | | |
| | FB-5D | 57 | 81 | | | | | | | |
| | NdFeB powder | | | 27.4 | 70.6 | | | | | |
| Stabilizer | Ethyl propionate | | | | | | | | | |
| | γ-Butyrolactone | 1.4 | 1.4 | 0.14 | 0.14 | | | | | |
| | Ethyl lactate | | | | | | | | | |
| | Dimethyl succinate | | | | | | | | | |
| Molecular weight α of curing | | 811 | 811 | 811 | 811 | 591 | 653 | 625 | 613 | 585 |
| agent | | | | | | | | | | |
| α/β value of curing agent | | 45 | 45 | 45 | 45 | 45 | 65 | 63 | 61 | 59 |
| Lap-shear strength (Cu) | | ◯ | ◯ | ◯ | ◯ | ⊚ | ⊚ | ⊚ | ⊚ | ⊚ |
| (adhesion) | | | | | | | | | | |
| Stability after 25° C. × 72 h | | ⊚ | ⊚ | ⊚ | ⊚ | ◯ | ◯ | ◯ | ◯ | ◯ |
| (storage stability at room | | | | | | | | | | |
| temperature) | | | | | | | | | | |
| TMA | CTE < Tg(ppm/° C.) | ⊚ | ⊚ | ⊚ | ⊚ | Δ | Δ | Δ | Δ | Δ |
| | (linear thermal | | | | | | | | | |
| | expansion) | | | | | | | | | |

TABLE 6

| Composition of epoxy resin | | Example | Example | Example | Example | Example | Example | Example | Example | Example |
|---|---|---|---|---|---|---|---|---|---|---|
| composition (parts by mass) | | 45 | 46 | 47 | 48 | 49 | 50 | 51 | 52 | 53 |
| Epoxy resin | EXA830CRP | 10 | 10 | 10 | 10 | 10 | 10 | 10 | 10 | 10 |
| | YED216 | | | | | | | | | |
| Curing agent | Compound A | | 2.25 | | | | | | | |
| | Compound B | | | 2 | 1 | | | | | |
| | Compound C | | | | | | | | | |
| | Compound D | | | | | | | | | |
| | Compound E | | 0.75 | 1 | | | | | | |
| | Compound F | | | | 1 | | | | | |
| | Compound G | | | | | | | | | |
| | Compound H | | | | | | | | | |
| | Compound I | | | | | | | | | |
| | Compound J | | | | | 2.25 | 2 | | | |
| | Compound K | | | | | | | 2.25 | | |
| | Compound L | | | | | | | | 2.5 | 2 |
| | Compound M | | | | | 0.75 | | | | |
| | Compound N | | | | 1 | | | 0.75 | 0.5 | |
| | Compound O | | | | | | | | | |
| | Compound P | | | | | | | | | |
| | Compound Q | 3 | | | | | 1 | | | 1 |
| | Curing agent A | | | | | | | | | |
| | Curing agent B | | | | | | | | | |
| | Curing agent C | | | | | | | | | |
| | Curing agent D | | | | | | | | | |
| Curing | 2E4MZ | | | | | | | | | |
| accelerator | | | | | | | | | | |
| Inorganic | SO-E2 | | | | | | | | | |
| filler | SE2200-SEJ | | | | | | | | | |
| | SE205-SEJ | | | | | | | | | |
| | SE203-SEJ | | | | | | | | | |
| | SE1050-SET | | | | | | | | | |
| | FB-5D | | | | | | | | | |
| | NdFeB powder | | | | | | | | | |
| Stabilizer | Ethyl propionate | | | | | | | | | |
| | γ-Butyrolactone | | | | | | | | | |
| | Ethyl lactate | | | | | | | | | |
| | Dimethyl succinate | | | | | | | | | |
| Molecular weight α of curing | | 320 | 574/687 | 542/687 | 542/797/625 | 839/653 | 839/320 | 811/625 | 591/625 | 591/320 |
| agent | | | | | | | | | | |
| α/β value of curing agent | | 64 | 48/57 | 54/57 | 54/47/63 | 47/65 | 47/64 | 45/63 | 45/63 | 45/64 |
| Lap-shear strength (Cu) | | ◯ | ⊚ | ⊚ | ⊚ | ⊚ | ⊚ | ⊚ | ⊚ | ⊚ |
| (adhesion) | | | | | | | | | | |
| Stability after 25° C. × 72 h | | ◯ | ◯ | ◯ | ◯ | ◯ | ◯ | ◯ | ◯ | ◯ |
| (storage stability at room | | | | | | | | | | |
| temperature) | | | | | | | | | | |
| TMA | CTE < Tg(ppm/° C.) | Δ | Δ | Δ | Δ | Δ | Δ | Δ | Δ | Δ |
| | (linear thermal | | | | | | | | | |
| | expansion) | | | | | | | | | |

TABLE 7

| Composition of epoxy resin | | Example | Example | Example | Example | Example | Example | Example | Example | Example |
|---|---|---|---|---|---|---|---|---|---|---|
| composition (parts by mass) | | 54 | 55 | 56 | 57 | 58 | 59 | 60 | 61 | 62 |
| Epoxy resin | EXA830CRP | 10 | 10 | 10 | 10 | 10 | 10 | 10 | 10 | 10 |
| | YED216 | | | | | | | | | |
| Curing agent | Compound A | | | 0.975 | 0.975 | | | 0.693 | | |
| | Compound B | | | | | | | | | |
| | Compound C | | | | | | | | | |
| | Compound D | | | | | | | | | |
| | Compound E | | | 0.325 | 0.325 | | | 0.231 | | |
| | Compound F | | | | | | | | | |
| | Compound G | | | | | | | | | |
| | Compound H | | | | | | | | | |
| | Compound I | | | | | | | | | |
| | Compound J | | | | | 0.975 | | | 0.693 | |
| | Compound K | 2.25 | 2.25 | | | | 0.975 | | | 0.693 |
| | Compound L | | | | | | | | | |
| | Compound M | | | | | 0.325 | | | 0.231 | |
| | Compound N | | | | | | 0.325 | | | 0.231 |
| | Compound O | | | | | | | | | |
| | Compound P | 0.75 | | | | | | | | |
| | Compound Q | | 0.75 | | | | | | | |
| | Curing agent A | | | 2.6 | 2.6 | 2.6 | 2.6 | | | |
| | Curing agent B | | | | | | | 1.8 | 1.8 | 1.8 |
| | Curing agent C | | | | | | | | | |
| | Curing agent D | | | | | | | | | |
| Curing | 2E4MZ | | | | | | | | | |
| accelerator | | | | | | | | | | |
| Inorganic | SO-E2 | | | | 13 | 13 | 13 | 13 | 13 | 13 |
| filler | SE2200-SEJ | | | | | | | | | |
| | SE205-SEJ | | | | | | | | | |
| | SE203-SEJ | | | | | | | | | |
| | SE1050-SET | | | | | | | | | |
| | FB-5D | | | | | | | | | |
| | NdFeB powder | | | | | | | | | |
| Stabilizer | Ethyl propionate | | | | | | | | | |
| | γ-Butyrolactone | | | | | | | | | |
| | Ethyl lactate | | | | | | | | | |
| | Dimethyl succinate | | | | | | | | | |
| Molecular weight α of curing | | 811/585 | 811/320 | 574/687 | 574/687 | 839/653 | 811/625 | 574/687 | 839/653 | 811/625 |
| agent | | | | | | | | | | |
| α/β value of curing agent | | 45/59 | 45/64 | 48/57 | 48/57 | 47/65 | 45/63 | 48/57 | 47/65 | 45/63 |
| Lap-shear strength (Cu) | | ⊚ | ⊚ | ⊚ | ◯ | ◯ | ◯ | ◯ | ◯ | ◯ |
| (adhesion) | | | | | | | | | | |
| Stability after 25° C. × 72 h | | ◯ | ◯ | ◯ | ⊚ | ⊚ | ⊚ | ⊚ | ⊚ | ⊚ |
| (storage stability at room | | | | | | | | | | |
| temperature) | | | | | | | | | | |
| TMA | CTE < Tg(ppm/° C.) | Δ | Δ | Δ | ⊚ | ⊚ | ⊚ | ⊚ | ⊚ | ⊚ |
| | (linear thermal | | | | | | | | | |
| | expansion) | | | | | | | | | |

TABLE 8

| Composition of epoxy resin composition (parts by | | Comparative | Comparative | Comparative | Comparative |
|---|---|---|---|---|---|
| mass) | | Example 1 | Example 2 | Example 3 | Example 4 |
| Epoxy resin | EXA830CRP | 10 | 10 | 10 | 10 |
| | YED216 | | | | |
| Curing agent | Compound A | | | | |
| | Compound B | | | | |
| | Compound C | | | | |
| | Compound D | | | | |
| | Compound E | | | | |
| | Compound F | | | | |
| | Compound G | | | | |
| | Compound H | | | | |
| | Compound I | | | | |
| | Compound J | | | | |
| | Compound K | | | | |
| | Compound L | | | | |
| | Compound M | | | | |
| | Compound N | | | | |
| | Compound O | | | | |
| | Compound P | | | | |
| | Compound Q | | | | |
| | Curing agent A | 3.6 | | | |
| | Curing agent B | | 2.8 | | |
| | Curing agent C | | | 9.3 | |
| | Curing agent D | | | | 0.8 |
| Curing accelerator | 2E4MZ | | | 0.05 | |
| Inorganic filler | SO-E2 | | | | |
| | SE2200-SEJ | | | | |
| | SE205-SEJ | | | | |
| | SE203-SEJ | | | | |
| | SE1050-SET | | | | |
| | FB-5D | | | | |
| | NdFeB powder | | | | |
| Stabilizer | Ethyl propionate | | | | |
| | γ-Butyrolactone | | | | |
| | Ethyl lactate | | | | |
| | Dimethyl succinate | | | | |
| Molecular weight α of curing agent | | 226 | 178 | 168 | 84 |
| α/β value of curing agent | | 113 | 89 | 56 | 21 |
| Lap-shear strength (Cu) (adhesion) | | Δ | Δ | X | X |
| Stability after 25° C. × 72 h (storage stability at | | X | X | ⊚ | ◯ |
| room temperature) | | | | | |
| TMA | CTE < Tg(ppm/° C.) | Δ | ◯ | Δ | X |
| | (linear thermal expansion) | | | | |

From the results of each table, the epoxy resin compositions using the curing agent having a specific molecular weight (molecular weight α) and molecular structure (ratio α/β) were confirmed to be excellent in adhesion.

From the results of each table, the epoxy resin compositions having a specific molecular weight and molecular structure and using the aminimide compound according to the present embodiment as a curing agent were confirmed to exhibit favorable storage stability.

On the other hand, poor storage stability or adhesion was confirmed when a compound having a molecular weight or a molecular structure that fell outside the scope of claims was used as a curing agent. Specifically, the liquid aromatic amine used in Comparative Examples 1 and 2 or the acid anhydride used in Comparative Example 3 produced poor adhesion, and poor storage stability was also confirmed in Comparative Examples 1 and 2.

From the results of Comparative Example 4, poor adhesion and linear thermal expansion were found when the ratio α/β of the curing agent was less than 30.

From the results of Examples 10 and 11, the addition of the inorganic filler was confirmed to exert excellent low linear thermal expansion.

From the results of Examples 12 to 17, the addition of the stabilizer having a specific structure was confirmed to further improve storage stability.

The present application is based on the Japanese patent application (Japanese Patent Application No. 2021-213746) filed in the Japan Patent Office on Dec. 28, 2021, the contents of which are incorporated herein by reference.

### INDUSTRIAL APPLICABILITY

The epoxy resin composition of the present invention has industrial applicability as, for example, encapsulants, adhesives, print substrate materials, coating materials, composite materials, semiconductor encapsulants such as underfills and moldings, conductive adhesives such as ACF, printed circuit boards such as solder resists and coverlay films, and composite materials such as prepregs prepared by the impregnation of glass fibers, carbon fibers, or the like.

1. An epoxy resin composition comprising
(A) epoxy resin, and
(B) a heteroatom-containing curing agent, wherein
molecular weight α of the heteroatom-containing curing agent (B) is 200≤α≤1200, and
ratio α/β of the molecular weight α to number β of heteroatoms in a structure of the heteroatom-containing curing agent (B) is 30≤α/β≤95.

2. The epoxy resin composition according to claim 1, wherein the heteroatom-containing curing agent (B) comprises an aminimide compound represented by the following formula (1), (2) or (3): 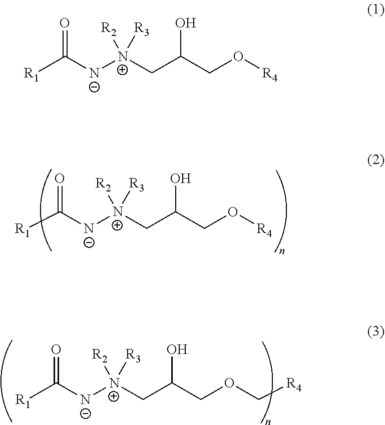
wherein each R₁ independently represents a hydrogen atom, or a monovalent or n-valent organic group having 1 to 15 carbon atoms and optionally having a hydroxy group, a carbonyl group, an ester bond, or an ether bond; R₂ and R₃ each independently represent an unsubstituted or substituted alkyl group having 1 to 12 carbon atoms, aryl group, aralkyl group, or heterocyclic ring having 7 or less carbon atoms in which R₂ and R₃ are linked to each other; each R₄ independently represents a hydrogen atom, or a monovalent or n-valent organic group having 1 to 30 carbon atoms and optionally containing an oxygen atom; and n represents an integer of 1 to 3.

3. The epoxy resin composition according to claim 2, wherein the n in the formula (2) or (3) is 2 or 3.

4. The epoxy resin composition according to claim 1, further comprising (C) an inorganic filler.

5. The epoxy resin composition according to claim 4, wherein a content of the inorganic filler (C) is more than 5% by mass and 98% by mass or less based on the whole epoxy resin composition.

6. The epoxy resin composition according to claim 1, further comprising (D) a stabilizer.

7. The epoxy resin composition according to claim 6, wherein the stabilizer (D) comprises a compound represented by the following formula (A) or (B): 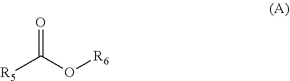
wherein R₅ and R₆ each independently represent a hydrogen atom, or a monovalent or n-valent organic group having 1 to 15 carbon atoms and optionally having a hydroxy group, a carbonyl group, an ester bond, or an ether bond; and n represents an integer of 2 to 3, 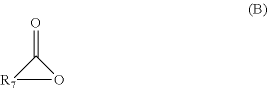
wherein R₇ represents a monovalent or n-valent organic group having 1 to 15 carbon atoms and optionally having a hydroxy group, a carbonyl group, an ester bond, or an ether bond; and n represents an integer of 2 to 3.

8. The epoxy resin composition according to claim 6, wherein a content of the stabilizer (D) is 1 part by mass or more and 30 parts by mass or less based on 100 parts by mass of the epoxy resin (A).

9. A cured product of the epoxy resin composition according to claim 1.

10. An encapsulant comprising the cured product according to claim 9.

11. The encapsulant according to claim 10, wherein the encapsulant is an encapsulant for a semiconductor.

12. An adhesive comprising the epoxy resin composition according to claim 1.
